(19) United States
(12) Patent Application Publication
(10) Pub. No.: US 2008/0302658 A1
(43) Pub. Date: Dec. 11, 2008

(54) OXIDE BODY, PIEZOELECTRIC DEVICE, AND LIQUID DISCHARGE DEVICE

(76) Inventors: Tsutomu Sasaki, Kanagawa-ken (JP); Yukio Sakashita, Kanagawa-ken (JP)

Correspondence Address: BIRCH STEWART KOLASCH & BIRCH, PO BOX 747, FALLS CHURCH, VA, 22040-0747, US

(21) Appl. No.: 12/134,830

(22) Filed: Jun. 6, 2008

(30) Foreign Application Priority Data
Jun. 8, 2007 (JP) 152382/2007

(51) Int. Cl. H01L 41/18; G01N 27/26

(52) U.S. Cl. 204/400; 252/62.9 R

(57) ABSTRACT

An oxide body formed of one or more of ferroelectric materials and antiferroelectric materials which exhibit asymmetric double hysteresis in a bipolar polarization-electric field characteristic obtained under a condition that the maximum value of an electric field applied to the oxide body and the magnitude of the minimum value of the electric field are equal (i.e., Emax=|Emin|), where the curve indicating the bipolar polarization-electric field characteristic has at least five points of inflection, and the maximum value of polarization of the oxide body and the magnitude of the minimum value of the polarization are different (i.e., Pmax≠|Pmin|).

### BACKGROUND OF THE INVENTION

1. Field of the Invention

The present invention relates to an oxide body being formed of a ferroelectric material or an antiferroelectric material and exhibiting a bipolar polarization-electric field characteristic. The present invention also relates to a piezoelectric device and a liquid discharge device using the above oxide body.

2. Description of the Related Art

Currently, the piezoelectric devices constituted by a piezoelectric body and electrodes are used in, for example, piezoelectric actuators installed in inkjet recording heads. In such piezoelectric devices, the piezoelectric body is formed of a ferroelectric material, and an electric field is applied from the electrodes to the piezoelectric body. For example, perovskite oxides such as PZT (lead titanate zirconate) are known as materials suitable for the ferroelectric body. The properties of the ferroelectric body with respect to variations in the electric field are evaluated by the polarization-electric field characteristic (P-E characteristic) and the like.

“Measurement of transverse piezoelectric properties of PZT thin films”, I. Kanno et al., Sensors and Actuators A: Physical, Vol. 107, Issue 1, pp. 68-74, 2003 indicates evaluations of the properties of c-axis oriented PZT films having a tetragonal structure. FIGS. 14A and 14B are quotations from “FIG. 2” and “FIG. 5” in the Kanno reference, which respectively show a polarization-electric field characteristic and a voltage-strain characteristic of an evaluated ferroelectric film. In the evaluated ferroelectric film, the direction of the applied electric field coincides with the orientation of the spontaneous-polarization axis, so that the 90-degree domain rotation does not occur although the 180-degree domain rotation occurs. The polarization-electric field characteristic of the ferroelectric film exhibits satisfactory squareness. That is, the changes in the polarization sharply occur in the vicinities of the coercive electric fields Ec1 and Ec2 due to the 180-degree domain rotation. In such a ferroelectric film, only the field-induced strain (expansion along the spontaneous-polarization axis in response to increase in the applied electric field) is produced, so that the strain linearly varies with variations in the electric field.

In the conventionally ferroelectric materials, the non-180-degree domain rotation such as the 90-degree domain rotation normally occurs. In such ferroelectric materials, the changes in the polarization in the vicinities of the coercive electric fields Ec1 and Ec2 are relatively gentle, the electric field-strain characteristic exhibits hysteresis, residual polarization Pr exists even after application of the electric field is stopped, and the bipolar polarization-electric field characteristic indicates a single hysteresis characteristic.

FIG. 15A schematically indicates a polarization-electric field characteristic loop and an electric field-strain characteristic loop (in bipolar actuation) of a conventional ferroelectric body in which the non-180-degree domain rotation occurs, and FIG. 15B shows schematically indicates an electric field-strain characteristic loop (in unipolar actuation) of the conventional ferroelectric body.

The bipolar polarization-electric field characteristic loop indicated in FIG. 15A has been obtained on the basis of measurement which has been performed by equally setting the magnitudes of the maximum and minimum values Emax and Emin of the applied electric field (i.e., Emax=|Emin|), and is approximately symmetric with respect to the origin of the coordinate plane of the polarization and the electric field. As indicated in the upper portion of FIG. 15A, the magnitudes of the maximum and minimum values Pmax and Pmin of the polarization of the ferroelectric body are approximately equal (i.e., Pmax≈|Pmin|), and the coercive electric field Ec1 on the negative-electric field side and the coercive electric field Ec2 on the positive-electric field side are also approximately equal (i.e., Ec2=|Ec1|).

Normally, the ferroelectric bodies are used after initialization processing called poling. Although the ferroelectric bodies contain a number of domains having spontaneous-polarization axes oriented along various directions before the poling, the orientations of the spontaneous-polarization axes of the domains are aligned on the whole by the poling. As indicated by the dotted curve beginning from the initial state and bearing the indication “In 1st Actuation” in each of the lower portion of FIG. 15A (the bipolar electric field-strain characteristic loop) and FIG. 15B (the unipolar electric field-strain characteristic loop), great displacement is produced by the poling as the initialization processing. However, after the poling, many domains are not restored to the initial state even when the application of the electric field is stopped. Therefore, the displacement in practical actuation after the initialization processing (i.e., the displacement under practical actuation conditions) is relatively small as indicated by the curves bearing the indication “In and After 2nd Actuation.” That is, the great displacement produced in the initialization processing of the ferroelectric body cannot be practically utilized in practical actuation of the ferroelectric body. In each of the lower portion of FIG. 15A and FIG. 15B, the gradient of the straight line 1 indicates the piezoelectric constant d in the actuation of the ferroelectric body in the range of the applied electric field between 0 and Emax.

FIG. 16A schematically indicates a polarization-electric field characteristic loop and an electric field-strain characteristic loop (in bipolar actuation) of a conventional antiferroelectric body, and FIG. 16B shows schematically indicates an electric field-strain characteristic loop (in unipolar actuation) of the conventional antiferroelectric body.

As indicated by the upward and downward arrows near the origin in the upper portion of FIG. 16A, when no electric field is applied to the antiferroelectric body, the orientations of the electric dipoles in the crystal lattices in the antiferroelectric body are alternately inverted in nanoscopic view, so that the antiferroelectric body does not exhibit residual polarization as a whole (i.e., the residual polarization Pr is nearly 0). When an electric field is applied to the antiferroelectric body, the orientations of the electric dipoles in the crystal lattices in the antiferroelectric body are aligned on the whole (as schematically indicated by the aligned arrows at the maximum and minimum values Emax and Emin of the applied electric field in the upper portion of FIG. 16A), i.e., the antiferroelectric body becomes similar to the ferroelectric body. However, when the application of the electric field is stopped, the antiferroelectric body is restored to the initial state. Therefore, the bipolar polarization-electric field characteristic loop of the antiferroelectric body exhibits the double hysteresis characteristic. As indicated in FIGS. 16A and 16B, in contrast to the ferroelectric body, substantially no difference is observed in the antiferroelectric body between the displacement in the first actuation and the displacement in and after the second actuation.

Specifically, the polarization-electric field characteristic loop indicated in FIG. 16A has been obtained on the basis of measurement which has been performed by equally setting the magnitudes of the maximum and minimum values Emax and Emin of the applied electric field (i.e., Emax=|Emin|), and is approximately symmetric with respect to the polarity of the polarization value. As indicated in the upper portion of FIG. 16A, the magnitudes of the maximum and minimum values Pmax and Pmin of the polarization of the antiferroelectric body are approximately equal (i.e., Pmax≈|Pmin|).

FIGS. 17A and 17B show examples of measurement data indicating polarization-electric field characteristics and voltage-strain characteristics of antiferroelectric bodies. FIGS. 17A and 17B are quotations from “FIG. 2” and “FIG. 8” in “Electrical and Electromechanical Properties of PbZrO₃ Thin Films Prepared by Chemical Solution Deposition”, H. Maiwa and N. Ichinose, Japanese Journal of Applied Physics, Vol. 40 Part 1, No. 9B, pp. 5507-5510, 2001. FIG. 17A shows measurement data indicating polarization-electric field characteristics of antiferroelectric bodies, and FIG. 17B shows measurement data indicating voltage-strain characteristics of the antiferroelectric bodies. In the data of FIGS. 17A and 17B, the antiferroelectric bodies are films of PbZrO₃ (PZ). Although the Maiwa reference does not indicate values of the piezoelectric constant, the present inventors have derived the piezoelectric constant d₃₃ of approximately 150 pm/V and the piezoelectric constant d₃₁ of approximately 75 pm/V (in actuation in the range of 0 to 400 kV/cm) from the gradient of the dashed line drawn over the measurement data of the polarization-electric field characteristics indicated in FIG. 17A. Although great displacement due to the phase transition between the antiferroelectric material and the ferroelectric material has been expected, the PZ films do not excel the films of PZT-based materials in the piezoelectric performance.

As indicated in the bipolar polarization-electric field characteristic loop of the antiferroelectric body of FIG. 16A, the displacement in the antiferroelectric body rapidly increases like a digital signal at a certain level of the applied electric field, and such displacement (which changes like a digital signal) is not suitable for use in piezoelectric actuators and the like. In addition, the antiferroelectric bodies have poor frequency characteristics. Therefore, the displacement performance deteriorates at the frequency above approximately 50 Hz although the displacement is satisfactory at the frequency of approximately 50 Hz or lower. Since the piezoelectric actuators are normally actuated at the frequencies of 100 Hz or higher, the antiferroelectric bodies are not suitable for use in piezoelectric actuators and the like.

Recently, ferroelectric materials which exhibit a symmetric double-hysteresis polarization-electric field characteristic have been reported. “Ferroelectric aging effect in hybrid-doped BaTiO₃ ceramics and the associated large recoverable electrostrain”, W. Liu et al., Applied Physics Letters, Vol. 89, 172908, 2006 reports that bulk BaTiO₃ ceramics which are codoped with acceptor ions of Mn and donor ions of Nb and randomly oriented have been produced, and aged at 60° C. for 64 hours, and symmetric double-hysteresis polarization-electric field characteristics have been observed in the bulk ceramic materials. FIGS. 18A and 18B are quotations from “FIG. 1” and “FIG. 3” in the Liu reference. FIG. 18A indicates polarization-electric field characteristic loops of the above materials, and FIG. 18B indicates electric field-strain characteristic loops of the above materials. Although the Liu reference does not indicate values of the piezoelectric constant, the present inventors have derived the greatest piezoelectric constant d₃₃ of approximately 550 pm/V and the piezoelectric constant d₃₁ of approximately 225 pm/V (in actuation in the range of 0 to 3 kV/cm) from the gradient of the dashed line drawn over the electric field-strain characteristic loop for BT-1Mn-0.5Nb bearing the reference (a) in FIG. 18B. Although containing no lead, great displacement is achieved in the above materials disclosed in the Liu reference.

Further, “In situ observation of reversible domain switching in aged Mn-doped BaTiO₃ single crystals”, L. X. Zhang and X. Ren, Physical Review B71, 174108-1-174108-8, 2005 reports that monocrystals of Mn-doped BaTiO₃ have been produced and aged at 80° C. for two weeks, and symmetric double-hysteresis polarization-electric field characteristics have been observed in the monocrystals.

Furthermore, the Liu reference and the Zhang reference report that 90-degree domain rotation occurs in the materials disclosed in these references, and indicate the following explanation on a mechanism realizing the above characteristics. (See “FIG. 4” in the Liu reference.)

The codoping with Mn and Nb or the doping with Mn produces movable point defects in ferroelectric domains in ferroelectric materials. When such doped materials are aged, the movable point defects move to stable positions and make pairs with oxygen defects so that the symmetry in the short-range order of the movable point defects coincides with the crystal symmetry in the ferroelectric domains. Therefore, the aging produces in the ferroelectric domains defect dipoles oriented along the spontaneous-polarization axes of the ferroelectric domains. Thereafter, although 90-degree domain rotation of the ferroelectric domains occurs when an electric field is applied to the above materials, the orientations of the defect dipoles do not change. Since the state in which the orientations of the polarization of the ferroelectric domains coincide with the orientations of the defect dipoles is stable, the orientations of the polarization of the ferroelectric domains are restored to the initial stable state when the application of the electric field is stopped. That is, since the defect dipoles facilitate restoration of the ferroelectric domains to the initial state, great displacement can be achieved in the above materials codoped with Mn and Nb or the doped with Mn even when the electric field is repeatedly increased and decreased, and the materials exhibit a double-hysteresis polarization-electric field characteristic.

When the ferroelectric bodies and the antiferroelectric bodies are used in piezoelectric actuators, the ferroelectric bodies and the antiferroelectric bodies are normally actuated in a unipolar mode. When application of the electric field to materials having a double-hysteresis polarization-electric field characteristic is stopped, the materials are restored to an initial state in which the residual polarization value Pr is zero or near to zero. Therefore, it is possible to expect to achieve greater displacement in the materials having a double-hysteresis polarization-electric field characteristic than in the materials having a single-hysteresis polarization-electric field characteristic, since relatively great residual polarization remains in the materials having the single-hysteresis polarization-electric field characteristics.

The present inventors have considered that if a material exhibiting in a bipolar polarization-electric field characteristic loop double hysteresis which is asymmetric with respect to the polarity of the polarization value (i.e., imbalanced toward the positive-polarization side or the negative-polarization side) is used, it is possible to achieve greater displacement by actuating the material in a unipolar mode on one of the positive-polarization side and the negative-polarization side on which greater displacement can be achieved. However, as long as the present inventors know, the material which exhibits in a bipolar polarization-electric field characteristic loop double hysteresis which is asymmetric with respect to the polarity of the polarization value has not yet been reported.

Since the size and weight of the electronic devices are decreasing and the functions of the electronic devices are being sophisticated, development of the piezoelectric devices which are to be mounted in such electronic devices and have reduced size and weight are proceeding. For example, in the field of the inkjet recording heads, techniques for increasing the density in the arrangement of piezoelectric devices are currently being studied in order to improve image quality. Further, in order to increase the density in the arrangement of the piezoelectric devices, the reduction of the thickness of ferroelectric bodies used in the piezoelectric devices are also being studied.

However, the Liu reference and the Zhang reference report production of only the bulk ceramics and bulk monocrystals as samples, and do not report a ferroelectric film having a double-hysteresis polarization-electric field characteristic. In addition, the techniques for producing a ferroelectric body disclosed in the Liu reference and the Zhang reference require longtime aging. Therefore, the manufacturing efficiency is low.

### SUMMARY OF THE INVENTION

The present invention has been made in view of such circumstances.

The first object of the present invention is to provide an oxide body formed of one or more of ferroelectric materials and antiferroelectric materials which exhibit asymmetric double hysteresis in a bipolar polarization-electric field characteristic loop and enables great displacement.

The second object of the present invention is to provide a ferroelectric film which exhibits an asymmetric double-hysteresis polarization-electric field characteristic and enables great displacement.

The third object of the present invention is to provide a piezoelectric device using a ferroelectric material which exhibits an asymmetric double-hysteresis polarization-electric field characteristic.

The fourth object of the present invention is to provide a liquid discharge device using a ferroelectric material which exhibits an asymmetric double-hysteresis polarization-electric field characteristic.

(I) In order to accomplish the first object, an oxide body according to the first aspect of the present invention is provided. The oxide body is formed of one or more of ferroelectric materials and antiferroelectric materials which exhibit asymmetric double hysteresis in a bipolar polarization-electric field characteristic obtained under a condition that the maximum value Emax of an electric field applied to the oxide body and the magnitude |Emin| of the minimum value Emin of the electric field are equal (i.e., Emax=|Emin|), where the curve (or loop) indicating the bipolar polarization-electric field characteristic has at least five points of inflection, and the maximum value Pmax of polarization of the oxide body and the magnitude |Pmin| of the minimum value Pmin of the polarization are different (i.e., Pmax≠|Pmin|).

The curve indicating the bipolar polarization-electric field characteristic may or may not pass through the origin of the coordinate plane of the polarization and the electric field. The number of the points of inflection is basically five in the case where the curve passes through the origin, and is basically six in the case where the curve does not pass through the origin.

In this specification, the curve indicating the bipolar polarization-electric field characteristic is a curve (or loop) containing both of a polarization-electric field characteristic curve obtained by measurement performed while varying the electric field from the minimum value Emin to the maximum value Emax and a polarization-electric field characteristic curve obtained by measurement performed while varying the electric field from the maximum value Emax to the minimum value Emin. Before determining the number of the points of inflection, the curve fitting and smoothing are performed on each of the polarization-electric field characteristic curve obtained while varying the electric field from Emin to Emax and the polarization-electric field characteristic carve obtained while varying the electric field from Emax to Emin. Therefore, points of inflection which are produced by small variations in the measurement data caused by measurement noise and the like are not counted among the points of inflection according to the present invention. When the degree of the measurement noise and the like is high, the curve fitting is performed after the measurement noise is removed by averaging, repeated accumulation, or the like.

The oxide body formed of one or more of ferroelectric materials and antiferroelectric materials which exhibit asymmetric double hysteresis in a bipolar polarization-electric field characteristic has been first realized by the present invention. As mentioned before, when application of the electric field to the materials having a double-hysteresis polarization-electric field characteristic is stopped, the materials are restored to an initial state in which the residual polarization value Pr is zero or near to zero. Therefore, it is possible to achieve greater displacement in the materials having a double-hysteresis polarization-electric field characteristic than in the materials having a single-hysteresis polarization-electric field characteristic, since relatively great residual polarization remains in the materials having a single-hysteresis polarization-electric field characteristic. In addition, since the double hysteresis in the bipolar polarization-electric field characteristic is asymmetric with respect to the polarity of the polarization value (i.e., imbalanced toward the positive-polarization side or the negative-polarization side), it is possible to achieve further great displacement by actuating the material in a unipolar mode on one of the positive-polarization side and the negative-polarization side on which greater displacement can be achieved.

Preferably, the oxide body according to the first aspect of the present invention may further have one or any possible combination of the following additional features (i) and (ii).

(i) The maximum value Pmax of the polarization of the oxide body is greater than the magnitude |Pmin| of the minimum value Pmin of the polarization. That is, in this case, the bipolar polarization-electric field characteristic is asymmetric with respect to the polarity of the polarization value, and the variations in the polarization in the range in which the polarization is positive are greater than the variations in the polarization in the range in which the polarization is negative.

(ii) The maximum value Pmax of the polarization of the oxide body is smaller than the magnitude |Pmin| of the minimum value Pmin of the polarization. That is, in this case, the bipolar polarization-electric field characteristic is asymmetric with respect to the polarity of the polarization value, and the variations in the polarization in the range in which the polarization is positive are smaller than the variations in the polarization in the range in which the polarization is negative.

In this specification, when the difference between the maximum value Pmax of the polarization of the oxide body and the magnitude |Pmin| of the minimum value Pmin of the polarization is greater than 10% of the areater one of the maximum value Pmax of the polarization of the oxide body and the magnitude |Pmin| of the minimum value Pmin of the polarization.

(iii) The oxide body according to the first aspect of the present invention is formed of one or more ferroelectric materials.

(iv) In the oxide body according to the first aspect of the present invention having the feature (iii), the one or more ferroelectric materials are one or more perovskite oxides, although the oxide body may contain inevitable impurities.

(v) In the oxide body according to the first aspect of the present invention having the feature (iv), the one or more ferroelectric materials are a perovskite oxide or a mixture of perovskite oxides, and each of the perovskite oxide and the perovskite oxides is expressed by a compositional formula ABO₃, A represents one or more A-site elements which are one or more of Pb, Ba, La, Sr, Bi, Li, Na, Ca, Cd, Mg, K, and the lanthanide elements, B represents one or more B-site elements which are one or more of Ti, Zr, V, Nb, Ta, Cr, Mo, W, Mn, Mg, Sc, Co, Cu, In, Sn, Ga, Zn, Cd, Fe, Ni, Hf, and Al, O represents oxygen, and the ratio of each of the total molar amount of atoms of the one or more A-site elements and the total molar amount of atoms of the one or more B-site elements to the molar amount of oxygen atoms in each perovskite oxide may deviate from 1:3 within a range in which a perovskite structure can be formed.

(vi) In at least one of the one or more perovskite oxides in the oxide body according to the first aspect of the present invention having the feature (v), the one or more A-site elements are one or more metal elements of Pb, Bi, Ba, Sr, Ca, La, and Mg, and the one or more B-site elements are a combination of one or more metal elements of Zr, Ti, Fe, and Al and one or more metal elements of Co, Mn, Mg, Ni, Zn, V, Nb, Ta, Cr, Mo, and W.

(vii) The oxide body according to the first aspect of the present invention having the feature (iii) contains one or more ferroelectric phases each having crystal orientation.

In this specification, the crystalline substance is determined to be “oriented” when the degree F of orientation measured by the Lotgerling technique is 80% or higher. The degree F of orientation is defined as

F(%)=(P−P0)/(1−P0)×100,

where P is the ratio of the total XRD (X-ray diffraction) intensity from an orientation plane to the total XRD intensity from all the crystal planes, and P0 is the value of P in the case where the sample is completely randomly oriented. In the case of the (001) orientation, P=ΣI(001)/ΣI(hkl), where I(hkl) is the XRD intensity from the crystal plane (hkl), ΣI(001) is the total XRD intensity from the crystal plane (001), and ΣI(hkl) is the total XRD intensity from all the crystal planes (hkl). For example, in the case of the (001) orientation in a perovskite crystal, P=I(001)/{I(001)+I(100)+I(101)+I(110)+I(111)}. When the sample is completely randomly oriented (i.e., when P=P0), F=0%. When the sample is completely oriented (i.e., when P=1), F=100%.

(viii) In the oxide body according to the first aspect of the present invention having the feature (vii), the one or more ferroelectric phases include one or both of a (100)-oriented ferroelectric phase and a (111)-oriented ferroelectric phase.

(ix) In the oxide body according to the first aspect of the present invention having the feature (viii), the one or more ferroelectric phases include a (100)-oriented tetragonal phase.

(x) In the oxide body according to the first aspect of the present invention having the feature (viii), the one or more ferroelectric phases include a (111)-oriented rhombohedral phase.

(xi) The oxide body according to the first aspect of the present invention having the feature (iii) has a composition equal or near to an MPB (morphotropic phase boundary) composition.

In this specification, the expression “the composition of a material is equal or near to an MPB composition” means that the composition of the material is in such a range that phase transition occurs when an electric field is applied to the material.

(xii) In the oxide body according to the first aspect of the present invention having the feature (vii), at least one of the one or more ferroelectric phases has crystal orientation along a first direction and a spontaneous-polarization axis along a second direction different from the first direction.

(xiii) In the oxide body according to the first aspect of the present invention having the feature (xii), the one or more ferroelectric phases are at least one of a rhombohedral phase having crystal orientation along approximately the <100> direction, a rhombohedral phase having crystal orientation along approximately the <110> direction, a tetragonal phase having crystal orientation along approximately the <110> direction, a tetragonal phase having crystal orientation along approximately the <111> direction, an orthorhombic phase having crystal orientation along approximately the <100> direction, and an orthorhombic phase having crystal orientation along approximately the <111> direction.

In this specification, the ferroelectric crystal is defined as being oriented approximately along an <abc> direction when the degree F of orientation along the <abc> axis is 80% or higher.

(xiv) In the oxide body according to the first aspect of the present invention having the feature (xii), at least part of each of at least one of the one or more ferroelectric phases transitions to at least one other ferroelectric phase each corresponding to a crystal system different from a crystal system corresponding to the ferroelectric phase, when an electric field is applied to the oxide body along a direction different from the second direction.

(xv) The oxide body according to the first aspect of the present invention is an oxide film formed on a substrate. This oxide film achieves the second object of the present invention.

The oxide film formed of one or more of ferroelectric materials and antiferroelectric materials which exhibit asymmetric double hysteresis in the bipolar polarization-electric field characteristic has been first realized by the present invention.

(II) In order to accomplish the third object, a piezoelectric device according to the second aspect of the present invention is provided. The piezoelectric device comprises a piezoelectric body realized by the oxide body according to the first aspect of the present invention having the feature (iii); and electrodes through which the electric field can be applied to the piezoelectric body along the thickness direction of the piezoelectric body.

(III) In order to accomplish the fourth object, a liquid discharge device according to the third aspect of the present invention is provided. The liquid discharge device comprises the piezoelectric device according to the second aspect of the present invention and a discharge member, and the discharge member includes a liquid-reserve chamber which reserves liquid, and a liquid-discharge outlet through which the liquid is discharged from the liquid-reserve chamber.

### DESCRIPTION OF THE DRAWINGS

FIG. 1 is a diagram schematically indicating a bipolar polarization-electric field hysteresis (characteristic) loop (i.e., bipolar P-E hysteresis loop), a bipolar electric field-strain characteristic loop, and a unipolar electric field-strain characteristic loop of a ferroelectric body according to the present invention.

FIG. 2 is a diagram schematically indicating points of inflection in the bipolar polarization-electric field hysteresis (characteristic) loop of FIG. 1.

FIG. 3 is a diagram provided for explaining a mechanism which realizes a double-hysteresis polarization-electric field characteristic of a ferroelectric body according to the present invention.

FIG. 4 is a schematically illustrating the orientations of polarization in ferroelectric domains and the orientations of defect dipoles in a (100)-oriented tetragonal ferroelectric material.

FIG. 5 is a schematically illustrating the orientations of polarization in ferroelectric domains and the orientations of defect dipoles in a (111)-oriented rhombohedral ferroelectric material.

FIG. 6 is a quotation from “FIG. 2” of Japanese Unexamined Patent Publication No. 2007-116091 (Japanese Patent Application No. 2006-188765), and is provided for explaining a structure in which phase transition occurs.

FIG. 7 is a cross-sectional view schematically illustrating a cross section of an essential portion of an inkjet recording head (as a liquid discharge device) having a piezoelectric device according to an embodiment of the present invention.

FIG. 8 is a diagram schematically illustrating an example of an inkjet recording apparatus having the inkjet recording head of FIG. 7.

FIG. 9 is a top view of a portion of the inkjet recording apparatus of FIG. 8.

FIG. 10 in a diagram schematically indicating a polarization-electric field hysteresis (characteristic) curve of a ferroelectric film in a concrete example.

FIG. 11 is a diagram schematically indicating a voltage-strain characteristic curve of the ferroelectric film in the concrete example.

FIG. 12 is a diagram schematically indicating a polarization-electric field hysteresis (characteristic) curve of a ferroelectric film in a comparison example.

FIG. 13 is a diagram schematically indicating a voltage-strain characteristic curve of the ferroelectric film in the comparison example.

FIG. 14A is a quotation from “FIG. 2” in the Kanno reference, which shows a polarization-electric field characteristic curve.

FIG. 14B is a quotation from “FIG. 5” in the Kanno reference, which shows a voltage-strain characteristic curve.

FIG. 15A is a diagram schematically indicating a polarization-electric field characteristic loop and an electric field-strain characteristic loop (in bipolar actuation) of a conventional ferroelectric body in which the non-180-degree domain rotation occurs.

FIG. 15B is a diagram schematically indicating an electric field-strain characteristic loop (in unipolar actuation) of the conventional ferroelectric body.

FIG. 16A is a diagram schematically indicating a polarization-electric field characteristic loop and an electric field-strain characteristic loop (in bipolar actuation) of a conventional antiferroelectric body in which the non-180-degree domain rotation occurs.

FIG. 16B is a diagram schematically indicating an electric field-strain characteristic loop (in unipolar actuation) of the conventional antiferroelectric body.

FIG. 17A is a quotation from “FIG. 2” in the Maiwa reference, and shows examples of measurement data indicating polarization-electric field characteristics of antiferroelectric bodies.

FIG. 17B is a quotation from “FIG. 8” in the Maiwa reference, and shows examples of measurement data indicating voltage-strain characteristics of the antiferroelectric bodies.

FIG. 18A is a quotation from “FIG. 1” in the Liu reference, and indicates polarization-electric field characteristic loops of the above materials.

FIG. 18B is a quotation from “FIG. 3” in the Liu reference, and indicates electric field-strain characteristic loops of the above materials.

### DESCRIPTION OF PREFERRED EMBODIMENTS

Preferred embodiments of the present invention are explained in detail below with reference to drawings.

### 1. Oxide Body

First, the oxide body according to the present invention is explained in detail below.

### 1.1 Polarization-Electric Field Characteristic

As mentioned before, the oxide body according to the present invention is formed of one or more of ferroelectric materials and antiferroelectric materials which exhibit asymmetric double hysteresis in a bipolar polarization-electric field characteristic obtained under a condition that the maximum value Emax of an electric field applied to the oxide body and the magnitude |Emin| of the minimum value Emin of the electric field are equal (i.e., Emax=|Emin|), where the curve indicating the bipolar polarization-electric field characteristic (i.e., the bipolar polarization-electric field characteristic curve) has at least five points of inflection, and the maximum value Pmax of polarization of the oxide body and the magnitude |Pmin| of the minimum value Pmin of the polarization are different (i.e., Pmax≠|Pmin|).

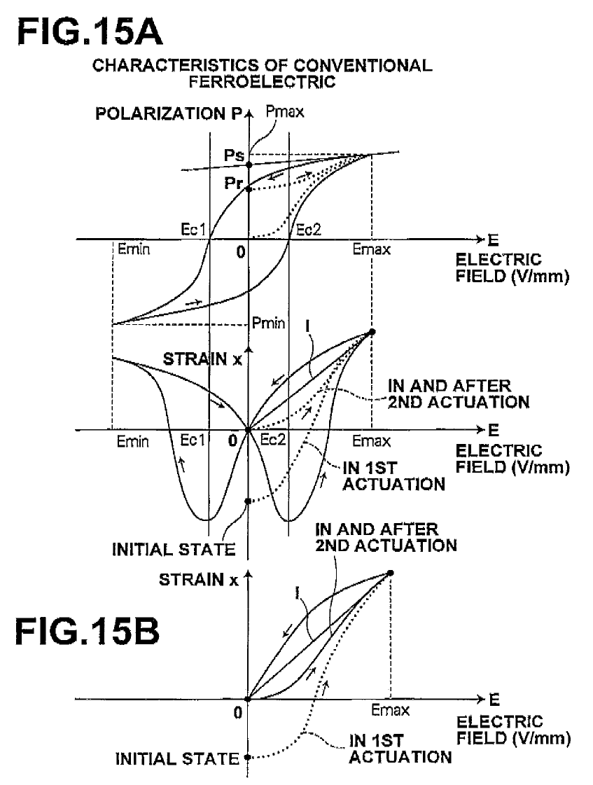

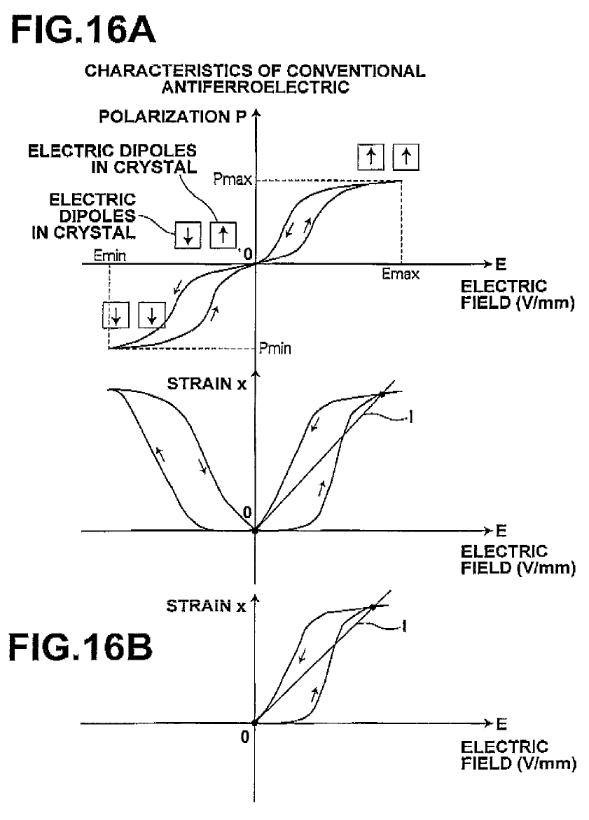

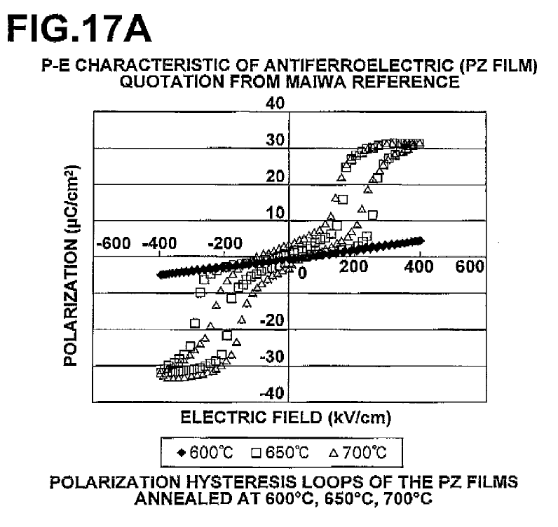

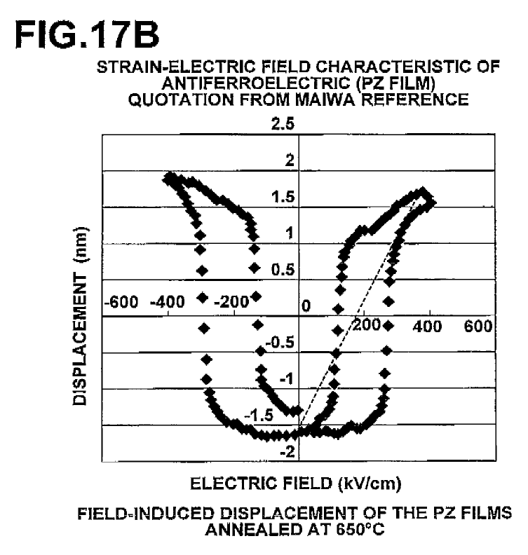

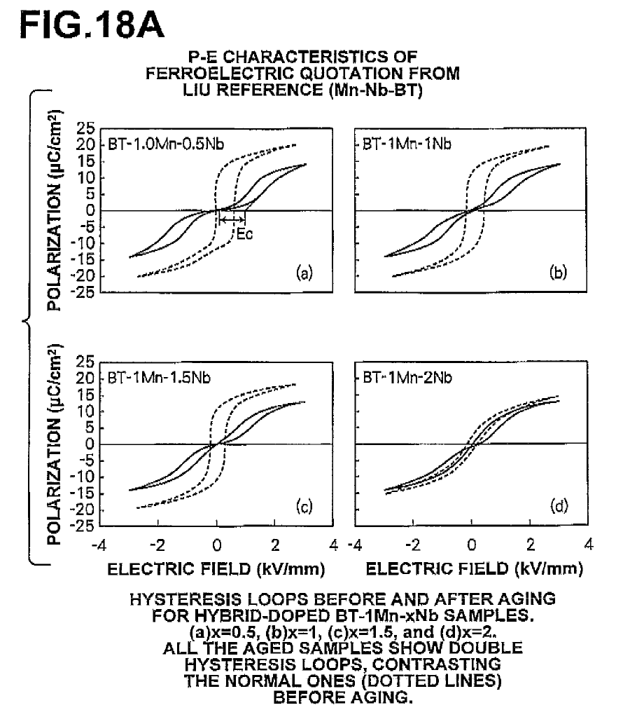

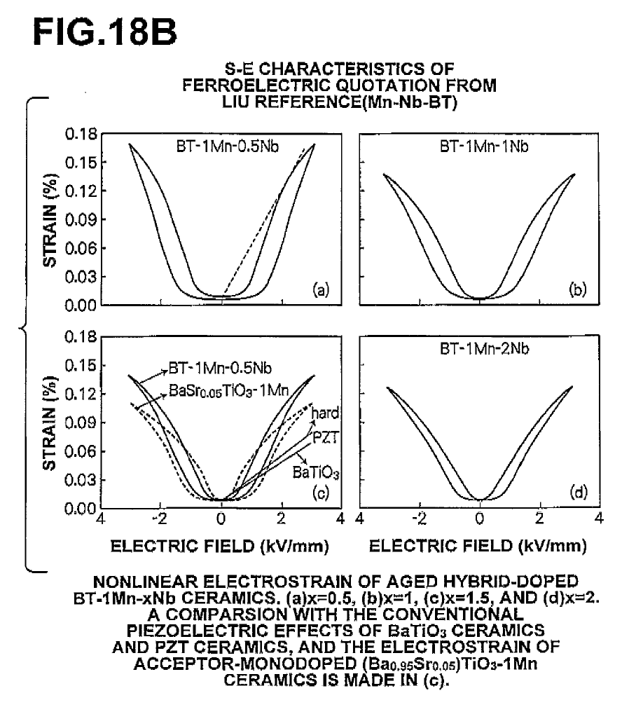

The number of points of inflection of the conventional single-hysteresis polarization-electric field characteristic loop indicated in FIG. 15A is two. When the bipolar polarization-electric field characteristic curve of a ferroelectric or antiferroelectric material exhibits double hysteresis, the bipolar polarization-electric field characteristic curve has five or more points of inflection.

The bipolar polarization-electric field characteristic curve of the oxide body according to the present invention may or may not pass through the origin of the coordinate plane of the polarization and the electric field. The number of the points of inflection is basically five in the case where the bipolar polarization-electric field characteristic curve passes through the origin, and is basically six in the case where the bipolar polarization-electric field characteristic curve does not pass through the origin.

The difference between the maximum value Pmax of polarization of the oxide body and the magnitude |Pmin| of the minimum value Pmin of the polarization (i.e., Pmax≠|Pmin|) means that the bipolar polarization-electric field characteristic (curve) is asymmetric with respect to the origin of the coordinate plane of the polarization and the electric field. In this case, the bipolar polarization-electric field characteristic (curve) may be imbalanced toward either the positive-polarization side or the negative-polarization side, i.e., either of Pmax and |Pmin| may be greater than the other.

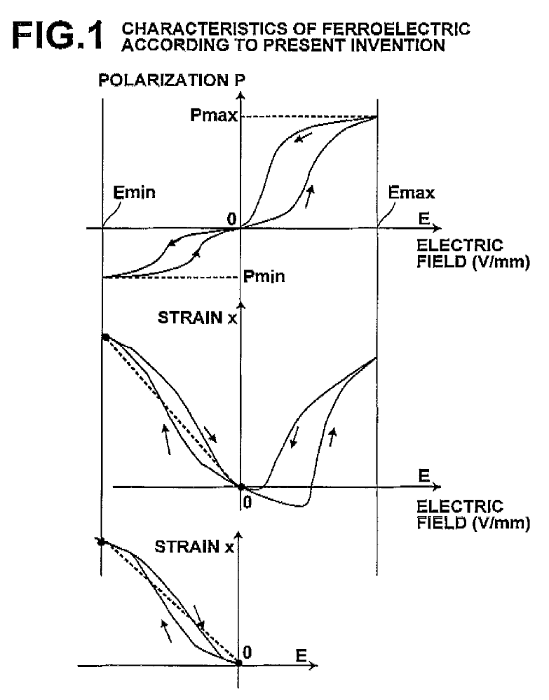

FIG. 1 schematically shows a bipolar polarization-electric field hysteresis (characteristic) loop (i.e., a bipolar P-E hysteresis loop), a bipolar electric field-strain characteristic loop, and a unipolar electric field-strain characteristic loop of a ferroelectric body according to an embodiment of the present invention. In the example of FIG. 1, the bipolar polarization-electric field hysteresis loop passes through the origin.

Very few ferroelectric materials which exhibit the double-hysteresis polarization-electric field characteristic have been reported until now. As long as the present inventors know, only the Liu reference and the Zhang reference have reported ferroelectric materials which exhibit the double-hysteresis polarization-electric field characteristic. However, the ferroelectric materials reported in the Liu reference and the Zhang reference exhibit symmetric double-hysteresis polarization-electric field characteristics, instead of the asymmetric double-hysteresis polarization-electric field characteristic. In addition, the Liu reference and the Zhang reference disclose only the bulk ceramics and bulk monocrystals of BaTiO₃-based materials.

The present inventors have first realized a PZT-based ferroelectric film exhibiting a double-hysteresis polarization-electric field characteristic (as indicated in detail in the description of the concrete example). The techniques for producing the ferroelectric materials disclosed in the Liu reference and the Zhang reference need longtime aging. On the other hand, the PZT-based ferroelectric film according to the present invention exhibiting the double-hysteresis polarization-electric field characteristic can be formed without the longtime aging. In addition, according to the present invention, the double-hysteresis polarization-electric field characteristic is asymmetric. Conventionally, either the ferroelectric body or the antiferroelectric body which exhibits a asymmetric double-hysteresis polarization-electric field characteristic (imbalanced toward the positive-polarization side or the negative-polarization side) has not been reported.

As mentioned before, the materials having the double-hysteresis polarization-electric field characteristic are restored to the initial state in which the residual polarization value Pr is zero or near to zero, when application of the electric field is stopped. On the other hand, relatively great residual polarization remains in the materials having the single-hysteresis polarization-electric field characteristic. Therefore, it is possible to expect to achieve greater displacement in the materials having the double-hysteresis polarization-electric field characteristic than in the materials having the single-hysteresis polarization-electric field characteristic.

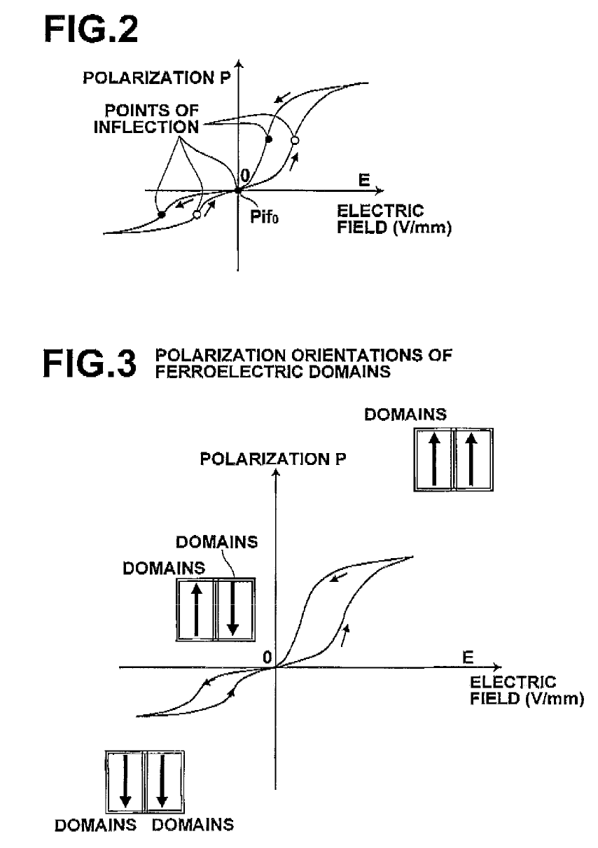

In the oxide body according to the present invention, the bipolar polarization-electric field characteristic curve may or may not pass through the origin. However, even when the bipolar polarization-electric field characteristic curve does not pass through the origin, it is preferable that the polarization value Pif₀ at the point of inflection nearest to the origin be near to zero. As indicated in FIG. 2, in the case where Pif₀=0, the bipolar polarization-electric field characteristic curve passes through the origin, i.e., the residual polarization value becomes zero. When Pif₀≈0, the bipolar polarization-electric field characteristic curve passes through a point near to the origin, so that it is possible to expect to achieve great displacement.

In the piezoelectric actuators, a piezoelectric body is normally actuated in the unipolar mode. In the case where the piezoelectric body is the oxide body according to the present invention (which exhibits the asymmetric double-hysteresis polarization-electric field characteristic imbalanced toward the positive-polarization side or the negative-polarization side), it is possible to actuate the oxide body in a unipolar mode on one of the positive-polarization side and the negative-polarization side on which greater change in the polarization can occur, and expect to achieve greater displacement. For example, in the case where the piezoelectric body is the oxide body according to the present invention of which the asymmetric double-hysteresis polarization-electric field characteristic is imbalanced toward the positive-polarization side, it is possible to consider that greater displacement can be achieved by actuating the oxide body in a unipolar mode on the positive-polarization side, in which greater change in the polarization can occur.

In practice, the electric field-strain characteristic can be affected by various characteristics, as well as the polarization-electric field characteristic. Therefore, it is possible to consider that in some cases, for example, a ferroelectric film exhibiting the asymmetric double-hysteresis polarization-electric field characteristic imbalanced toward the positive-polarization side can achieve greater displacement when the ferroelectric film is actuated in a unipolar mode in the range of negative polarization values (which is narrower than the range of positive polarization values) than when the ferroelectric film is actuated in a unipolar mode in the range of positive polarization values. FIG. 1 shows the characteristics in one of such cases. For example, in the case where relatively great loss is caused by 180-degree domain rotation (which does not contribute to the displacement) in the actuation on the positive-electric field side, and no loss is caused by the 180-degree domain rotation in the actuation on the negative-electric field side, it is possible to expect that the greater displacement can be achieved by the actuation in the unipolar mode in the range of negative polarization values (which is narrower than the range of positive polarization values), and the piezoelectric strain due to the engineered-domain effect, phase transition, non-180-degree domain rotation, and the like can be realized by the actuation on the negative-electric field side.

The oxide body according to the present invention exhibits the asymmetric double-hysteresis polarization-electric field characteristic imbalances toward the positive-polarization side or the negative-polarization side, and do not exhibit the same electric field-strain characteristics on the positive-electric field side and the negative-electric field side. That is, the strain achieved by the actuation of the oxide body on one of the positive-electric field side and the negative-electric field side is greater than the strain achieved by the actuation on the other of the positive-electric field side and the negative-electric field side, i.e., greater displacement can be obtained when the material is actuated in a unipolar mode on the one of the positive-electric field side and the negative-electric field side.

It is possible to expect to achieve greater displacement in the unipolar actuation when the degree of the asymmetry in the polarization-electric field hysteresis is greater (i.e., when the difference between Pmax and |Pmin| is greater). It is preferable that the difference between the maximum value Pmax of the polarization of the oxide body according to the present invention and the magnitude |Pmin| of the minimum value Pmin of the polarization be greater than 10% of the greater one of the maximum value Pmax of the polarization of the oxide body and the magnitude |Pmin| of the minimum value Pmin of the polarization.

As explained in the “Description of the Related Art,” the antiferroelectric materials are not suitable for use in piezoelectric actuators and the like, since the displacement in the antiferroelectric body rapidly increases like a digital signal at a certain level of the applied electric field, and the antiferroelectric materials have poor frequency characteristics. Therefore, the realization of the ferroelectric body exhibiting the asymmetric double-hysteresis polarization-electric field characteristic is particularly advantageous.

Although the mechanism of realizing the double-hysteresis polarization-electric field characteristic of the ferroelectric body according to the present invention has not been theoretically clarified, the present inventors consider the mechanism as follows.

As explained in the “Description of the Related Art,” when no electric field is applied to an antiferroelectric body, the orientations of the electric dipoles in the crystal lattice in the antiferroelectric body are alternately inverted in nanoscopic view, so that the antiferroelectric body does not exhibit residual polarization as a whole (i.e., the residual polarization Pr is nearly 0). The present inventors consider that the ferroelectric body according to the present invention exhibiting the polarization-electric field characteristic of FIG. 1 is in a state which is similar to the antiferroelectric body when no electric field is applied to the ferroelectric body.

Although details of the microscopic states of the crystal lattices or the domains have not been theoretically clarified, the present inventors consider the mechanism of realizing the double-hysteresis polarization-electric field characteristic as follows.

FIG. 3 is a diagram provided for indicating a mechanism which realizes the double-hysteresis polarization-electric field characteristic of the ferroelectric body according to the present invention. When no electric field is applied to the ferroelectric body according to the present invention exhibiting the double-hysteresis polarization-electric field characteristic as indicated in FIG. 1, the polarization of the domains is stabilized so that the polarization of each domain is cancelled by the polarization of adjacent domains (as schematically indicated by upward and downward arrows near the origin in FIG. 3), and therefore the ferroelectric body does not exhibit residual polarization as a whole (i.e., the residual polarization Pr is nearly 0). When an electric field is applied to the above ferroelectric body, the orientations of the polarization of the domains are aligned on the whole (as schematically indicated by the aligned arrows near the maximum and minimum of the applied electric field in FIG. 3), so that the polarization of the ferroelectric body is microscopically observed. When the electric field applied to the ferroelectric body is stopped, the ferroelectric body is restored to the initial state (in which the ferroelectric body is stable and similar to the antiferroelectric body). Thus, the bipolar polarization-electric field characteristic curve of the ferroelectric body according to the present invention exhibits the double hysteresis and passes through the origin of the coordinate plane of the polarization and the electric field.

The bipolar polarization-electric field characteristic curve of the ferroelectric body according to the present invention may not pass through the origin. However, even in this case, the residual polarization Pr in the ferroelectric body according to the present invention is smaller than the residual polarization in the conventional ferroelectric body exhibiting the single hysteresis polarization-electric field characteristic as indicated in the FIG. 15A. Therefore, it is possible to consider that the ferroelectric body according to the present invention having the bipolar polarization-electric field characteristic curve which does not pass through the origin is in an intermediate state between the state of the ferroelectric body according to the present invention having the bipolar polarization-electric field characteristic curve which passes through the origin as indicated in the FIG. 3 and the state of the conventional ferroelectric body exhibiting the single hysteresis polarization-electric field characteristic as indicated in the FIG. 15A.

The polarization of each domain is assumed to be alternately inverted by 180 degrees in the example of FIG. 3. Normally, the ferroelectric body is used in a ferroelectric (piezoelectric) device, which is formed by sandwiching the ferroelectric body (as a piezoelectric body) by an upper electrode and a lower electrode. One of the upper electrode and the lower electrode is used as a grand electrode (to which a voltage fixed to 0V is applied), and the other is used as an address electrode (to which a variable voltage is applied). Normally, the lower electrode is used as the grand electrode, and the upper electrode is used as the address electrode. In FIG. 3, the upward arrows indicate upward polarization, and the downward arrows indicate downward polarization. In the upward-polarized domains, the upper-electrode side is positively polarized, and the lower-electrode side is negatively polarized. In the downward-polarized domains, the upper-electrode side is negatively polarized, and the lower-electrode side is positively polarized.

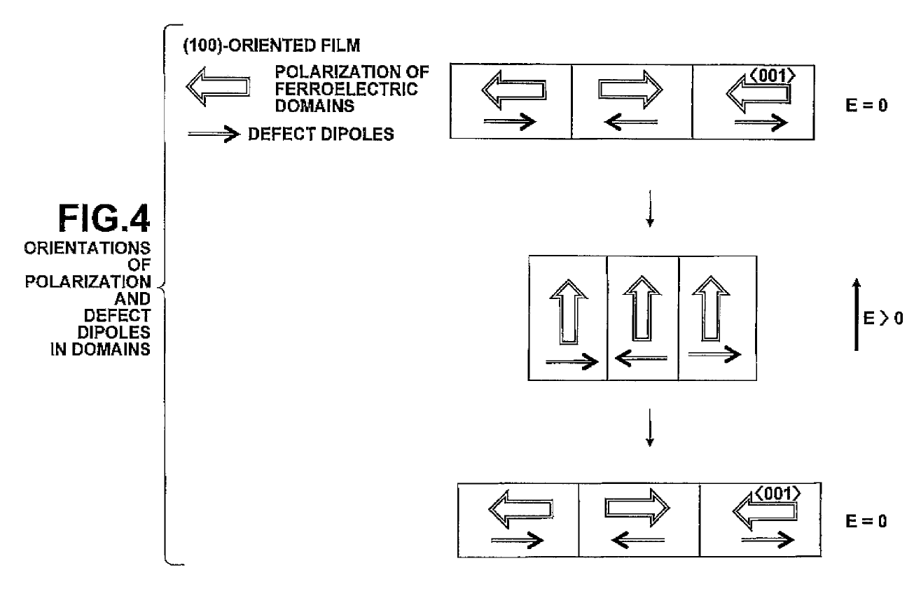

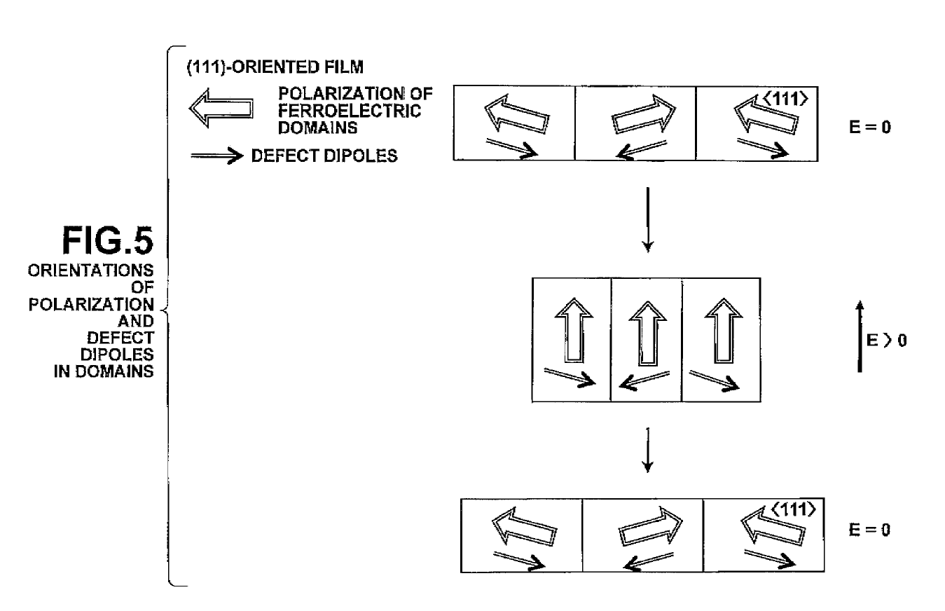

Although the orientations of the polarization of the domains are schematically indicated as completely upward or completely downward in FIG. 3, generally, the polarization of the domains when no electric field is applied to the ferroelectric body may be oblique or perpendicular to the direction along which the electric field is to be applied, as indicated in FIGS. 4 and 5. In the example of FIG. 5, the orientations of the polarization of the domains when no electric field is applied are slightly tilted from the direction perpendicular to the direction of the electric field.

Although the factor which causes the asymmetric double-hysteresis polarization-electric field characteristic of the ferroelectric body according to the present invention has not been theoretically clarified, the present inventors consider that the influence of the space charges in the crystal lattices realizes the asymmetric double-hysteresis polarization-electric field characteristic. Specifically, the present inventors consider that defect dipoles are produced in the ferroelectric domains by the action of the space charges, and realize the asymmetric double-hysteresis polarization-electric field characteristic.

The space charges can be controlled by one or a combination of introduction of lattice defects by doping with donor ions having a valence greater than the valence of the atoms to be substituted, introduction of lattice defects by doping with acceptor ions having a valence smaller than the valence of the atoms to be substituted, introduction of lattice defects by oxygen defects, the crystal orientation of the ferroelectric body, the composition and/or crystal orientation of an underlying layer (i.e., a layer underlying the ferroelectric body), and the film-formation condition such as the film-formation temperature and the cooling process after the film formation.

The form of the ferroelectric body according to the present invention can be designed as appropriate. For example, the ferroelectric body according to the present invention may have the form of a film or a sintered ceramic body. In the field of the inkjet recording heads and the like, techniques for increasing the density in the arrangement of a number of piezoelectric elements (devices) are currently being studied in order to improve image quality. In order to increase the density in the arrangement of piezoelectric elements, techniques for reduction in the thicknesses of the piezoelectric devices are also being studied. In order to reduce the thickness of the piezoelectric device, the ferroelectric body is preferably a ferroelectric film, and more preferably a thin ferroelectric film having the thickness of 20 micrometers or smaller.

In the ferroelectric films formed on a substrate, the stress caused by the restoring force of the substrate which acts in the direction of restoring the substrate to the original shape and the difference in the thermal expansion coefficient between the ferroelectric film and the substrate are considered to affect the polarization-electric field characteristic.

As mentioned before, the techniques for producing the ferroelectric materials disclosed in the Liu reference and the Zhang reference need longtime aging. On the other hand, the present inventors have confirmed that when ferroelectric films or bodies are produced by film formation or baking through a non-thermal equilibrium process such as PLD (pulsed-laser deposition), sputtering, plasma CVD (chemical vapor deposition), or the discharge plasma sintering, introduction of the lattice defects and the space charges accompanying the lattice defects is easy, the double-hysteresis polarization-electric field characteristic can be realized without longtime aging, and the hysteresis characteristic can be easily controlled. In addition, the present inventors have also confirmed that when postannealing at the temperature approximately 50° C. higher than the Curie temperature Tc is performed after film formation, the double-hysteresis polarization-electric field characteristic can be realized without longtime aging, and the hysteresis characteristic can be easily controlled. In this case, the postannealing may include the annealing realized by controlling the cooling process after the film formation. Thus, it is preferable that the ferroelectric body according to the present invention be a ferroelectric film formed on a substrate.

The present inventors consider that after a ferroelectric film is formed by PLD, sputtering, or the like, the defect dipoles are produced by the action of the space charges in ferroelectric domains in the most stable manner during the process of cooling the formed ferroelectric film to the ordinary temperature. In addition, the present inventors also consider that the space charges are likely to be produced in the vicinity of the boundary between the ferroelectric film and the underlying layer, and realize the special (asymmetric double-hysteresis) polarization-electric field characteristic.

The present inventors consider that the antiferroelectric body according to the present invention is similar to the ferroelectric body according to the present invention in the mechanism of realizing the asymmetric double-hysteresis polarization-electric field characteristic of the antiferroelectric body according to the present invention and the manner of controlling the asymmetric double hysteresis in the polarization-electric field characteristic, except that the antiferroelectric body does not exhibit residual polarization as a whole when no electric field is applied to the antiferroelectric body since the orientations of the electric dipoles in the crystal lattice in the antiferroelectric body are alternately inverted in nanoscopic view. In addition, the antiferroelectric body according to the present invention is also similar to the ferroelectric body according to the present invention in that the antiferroelectric body is preferably an antiferroelectric film formed on a substrate.

### 1.2 Composition

The composition of the ferroelectric body according to the present invention is not specifically limited as long as the ferroelectric body has the characteristics according to the present invention. For example, the ferroelectric body according to the present invention may be formed of one or more perovskite oxides, although the ferroelectric body may further contain inevitable impurities. In this case, it is preferable that the one or more perovskite oxides have composition expressed by the compositional formula ABO₃, where A represents one or more A-site elements which are one or more of Pb, Ba, La, Sr, Bi, Li, Na, Ca, Cd, Mg, K, and the lanthanide elements, B represents one or more B-site elements which are one or more of Ti, Zr, V, Nb, Ta, Cr, Mo, W, Mn, Mg, Sc, Co, Cu, In, Sn, Ga, Zn, Cd, Fe, Ni, Hf, and Al, and O represents oxygen. Although the ratio of each of the total molar amount of atoms of the one or more A-site elements and the total molar amount of atoms of the one or more B-site elements to the molar amount of oxygen atoms in each of the one or more perovskite oxides is normally 1:3, the ratio may deviate from 1:3 within a range in which a perovskite structure can be formed.

Specifically, each of the one or more perovskite oxides may be one of the lead-containing compounds (1) and the nonlead compounds (2) indicated below, or a mixture of crystals of two or more of the lead-containing compounds (1) and the nonlead compounds (2).

(1) Lead-containing compounds such as lead titanate, lead titanate zirconate (PZT), lead zirconate, lead lanthanum titanate, lead lanthanum titanate zirconate, lead magnesium niobate-lead zirconium titanate, lead nickel niobate-lead zirconium titanate, lead zinc niobate-lead zirconium titanate, and the like

(2) Nonlead compounds such as barium titanate, barium strontium titanate, bismuth sodium titanate, bismuth potassium titanate, sodium niobate, potassium niobate, lithium niobate, bismuth, and the like

Furthermore, in order to improve the electric characteristics, it is preferable that the ferroelectric body according to the present invention contain ions of one or more of the metals Mg, Ca, Sr, Ba, Bi, Nb, Ta, W, and the lanthanide elements Ln. The lanthanide elements Ln include La, Ce, Pr, Nd, Sm, Eu, Gd, Tb, Dy, Ho, Er, Tm, Yb, and Lu.

Moreover, it is particularly preferable that the ferroelectric body according to the present invention contain a perovskite oxide in which the one or more A-site elements are one or more metal elements of Pb, Bi, Ba, Sr, Ca, La, and Mg, and the one or more B-site elements are a combination of one or more metal elements of Zr, Ti, Fe, and Al and one or more metal elements of Co, Mn, Mg, Ni, Zn, V, Nb, Ta, Cr, Mo, and W. The above perovskite oxide preferably contained in the ferroelectric body according to the present invention is a compound produced by substituting part of the B-site atoms of a +2/+4 type perovskite oxide with one or more acceptors each having a valence smaller than the valence of the part of the B-site atoms and/or one or more donors each having a valence greater than the valence of the part of the B-site atoms, where the +2/+4 type perovskite oxide is a perovskite oxide in which one or more divalent metal elements reside in the A sites, and one or more quadrivalent metal elements reside in the B sites. For example, PZT is a +2/+4 type perovskite oxide. In the case where the ferroelectric body according to the present invention contains the above perovskite oxide, it is relatively easy to realize the asymmetric double hysteresis in the polarization-electric field characteristic according to the present invention. The present inventors consider that the substituent elements produce space charges in the crystal lattices and enable control of the asymmetric double hysteresis in the polarization-electric field characteristic. The present inventors have successfully realized the asymmetric double hysteresis in the polarization-electric field characteristic according to the present invention in firms of intrinsic PZT and Nb-doped PZT. In particular, the present inventors have successfully realized a film of Nb-doped PZT which exhibits an asymmetric double hysteresis polarization-electric field characteristic curve passing through the origin of the coordinate plane of the polarization and the electric field.

Alternatively, the space charges can also be introduced by intentionally producing A-site defects or oxygen defects, instead of the B-site doping with the acceptor ions and/or donor ions.

### 1.3 Crystal Structure

The crystal structure of the ferroelectric body according to the present invention is explained below.

It is preferable that the ferroelectric body according to the present invention contain a ferroelectric phase having crystal orientation.

The piezoelectric strain includes the following types (1) to (4).

(1) Normal field-induced strain (i.e., expansion and contraction along a direction in which an electric field is applied) which is produced in response to increase and decrease in the strength of the electric field when the direction of the electric field coincides with the direction of a vector component of the spontaneous-polarization axis

(2) Piezoelectric strain which is produced by reversible rotation of a polarization axis by a rotation angle different from 180 degrees (i.e., reversible non-180-degree domain rotation) when increase and decrease in the strength of the electric field causes the reversible rotation

(3) Piezoelectric strain which is produced by a volume change caused by phase transition of a crystal when increase and decrease in the strength of the electric field causes the phase transition

(4) Piezoelectric strain which is produced by the engineered-domain effect in the case where the ferroelectric body being formed of a material in which phase transition is caused by application of an electric field, having an oriented crystal structure, and containing a ferroelectric phase oriented in a direction different from the orientation of the spontaneous-polarization axis (When the engineered-domain effect is utilized, the electric field ray be applied to the ferroelectric body under either a condition in which phase transition occurs, or a condition in which phase transition does not occur.)

The piezoelectric strain produced by the reversible non-180-degree domain rotation is disclosed in Japanese Unexamined Patent Publication No. 2004-363557, the piezoelectric strain produced by the phase transition is disclosed in Japanese Patent No. 3568107, and the piezoelectric strain produced by the engineered-domain effect is disclosed by “Ultrahigh strain and piezoelectric behavior in relaxor based ferroelectric single crystals”, S. E. Park and T. R. Shrout, Journal of Applied Physics, Vol. 82, pp. 1804-1811, 1997 and Japanese Unexamined Patent Publication No. 2007-116091 (which is hereinafter referred to as JP2007-116091A, and corresponds to Japanese Patent Application No. 2006-188765, the inventors of which include one of the present inventors, Yukio Sakashita).

It is possible to achieve a desired magnitude of piezoelectric strain by utilizing one or a combination of all or part of the above types (1) to (4) of piezoelectric strain. When a ferroelectric body contains an oriented crystal structure corresponding to one or more of the mechanisms by which the above types of piezoelectric strain are produced, the piezoelectric strain in the ferroelectric body increases. For example, the ferroelectric body according to the present invention may contain a (100)-oriented ferroelectric phase and/or a (111)-oriented ferroelectric phase. Specifically, the ferroelectric body according to the present invention may contain a (100)-oriented tetragonal phase and/or a (111)-oriented rhombohedral phase. Further, the ferroelectric body according to the present invention may have composition equal or near to the MPB (morphotropic phase boundary) composition.

The reversible non-180-degree domain rotation can occur in the ferroelectric body containing a (100)-oriented ferroelectric phase and/or a (111)-oriented ferroelectric phase. The magnitude of the piezoelectric strain produced by the reversible non-180-degree domain rotation is far greater than the magnitude of the normal field-induced strain.

As explained before, the present inventors consider that when the space charges are introduced, defect dipoles are produced by the action of the space charges, and realize the special (asymmetric double-hysteresis) polarization-electric field characteristic. FIG. 4 schematically shows the orientations of polarization in ferroelectric domains and the orientations or defect dipoles in a (100)-oriented tetragonal ferroelectric material, and FIG. 5 schematically shows the orientations of polarization in ferroelectric domains and the orientations of defect dipoles in a (111)-oriented rhombohedral ferroelectric material.

The upper part of FIG. 4 shows the states of the ferroelectric domains when no electric field is applied to the (100)-oriented tetragonal ferroelectric material (i.e., E=0). At this time, the orientations of the polarization of the ferroelectric domains are along the spontaneous-polarization axes of the ferroelectric domains, which are along the <001> directions, and perpendicular to the direction in which the electric field is to be applied. The upper part of FIG. 5 shows the states of the ferroelectric domains when no electric field is applied to the (111)-oriented rhombohedral ferroelectric material (i.e., E=0). At this time, the orientations of the polarization of the ferroelectric domains are along the spontaneous-polarization axes of the ferroelectric domains, which are along the <111> directions, and oblique to the direction in which the electric field is to be applied.

The present inventors consider that when no electric field is applied to the ferroelectric body according to the present invention exhibiting the asymmetric double-hysteresis polarization-electric field characteristic, the polarization of the domains is stabilized so that the polarization of each domain is cancelled by the polarization of adjacent domains, and therefore the ferroelectric body does not exhibit residual polarization as a whole. In addition, the present inventors consider that after a ferroelectric film is formed by PLD, sputtering, or the like, defect dipoles are produced by the action of the space charges in ferroelectric domains in the most stable manner during the process of cooling the ferroelectric film to the ordinary temperature. Specifically, the present inventors consider that in the ferroelectric domains illustrated in the upper part of each of FIGS. 4 and 5, the defect dipoles are produced along such a direction that the defect dipoles in each ferroelectric domain cancel or reduce the polarization of the ferroelectric domain.

The middle part of FIG. 4 shows the states of the ferroelectric domains when the electric field (E>0) is applied to the (100)-oriented tetragonal ferroelectric material, and the middle part of FIG. 5 shows the states of the ferroelectric domains when the electric field (E>0) is applied to the (111)-oriented rhombohedral ferroelectric material. The present inventors consider that when the electric field (E>0) is applied, non-190-degree domain rotation occurs so that the orientations of the polarization of the ferroelectric domains are aligned with the direction of the applied electric field, although the orientations of the defect dipoles are unchanged, as illustrated in the middle part of each of FIGS. 4 and 5.

The lower part of FIG. 4 shows the states of the ferroelectric domains when the application of the electric field to the (100)-oriented tetragonal ferroelectric material is stopped, and the lower part of FIG. 5 shows the states of the ferroelectric domains when the application of the electric field to the (111)-oriented rhombohedral ferroelectric material is stopped. As illustrated in the lower part of each of FIGS. 4 and 5, when the electric field is stopped, the ferroelectric domains are restored to the initial state (i.e., the original stable state). As mentioned before, in the initial state, the defect dipoles are oriented along such a direction that the defect dipoles in each ferroelectric domain cancel or reduce the polarization of the ferroelectric domain. The present inventors consider that since the initial state is stable, the existence of the space charges facilitate the restoration of the ferroelectric domains to the initial state, so that it is possible to stably achieve piezoelectric strain by the reversible non-180-degree domain rotation. In other words, the ferroelectric domains can be easily restored by a kind of attractive action of the defect dipoles. In addition, the present inventors consider that the ferroelectric materials of FIGS. 4 and 5 exhibit the special hysteresis (i.e., the asymmetric double-hysteresis) in the polarization-electric field characteristic by the above action of the defect dipoles.

Further, when no electric field is applied, the orientations of the polarization of the ferroelectric domains in the (100)-oriented tetragonal ferroelectric material illustrated in FIG. 4 are perpendicular to the direction of the electric field to be applied, and the orientations of the polarization of the ferroelectric domains in the (111)-oriented rhombohedral ferroelectric material illustrated in FIG. 5 are tilted from the direction perpendicular to the direction of the electric field to be applied. Therefore, the present inventors consider that the piezoelectric strain caused by the reversible non-180-degree domain rotation is greater in the (100)-oriented tetragonal ferroelectric material than in the (111)-oriented rhombohedral ferroelectric material. Thus, it is particularly preferable that the ferroelectric body according to the present invention contain a (100)-oriented ferroelectric phase.

Furthermore, it is possible to expect relatively great piezoelectric strain in the case where the structure realizing the reversible non-180-degree domain rotation as illustrated in FIGS. 4 and 5 and the structure realizing the phase transition are combined.

Hereinbelow, a ferroelectric body having the structure realizing the phase transition, which is also disclosed in JP2007-116091A, is explained. Generally, the ferroelectric body having the structure realizing the phase transition contains a first ferroelectric phase at least part of which transitions to a second ferroelectric phase when an electric field is applied to the ferroelectric body, and the first and second ferroelectric phases have crystal structures corresponding to different crystal systems. In order to simplify the explanation, it is assumed that the ferroelectric body is initially formed with only the first ferroelectric phase.

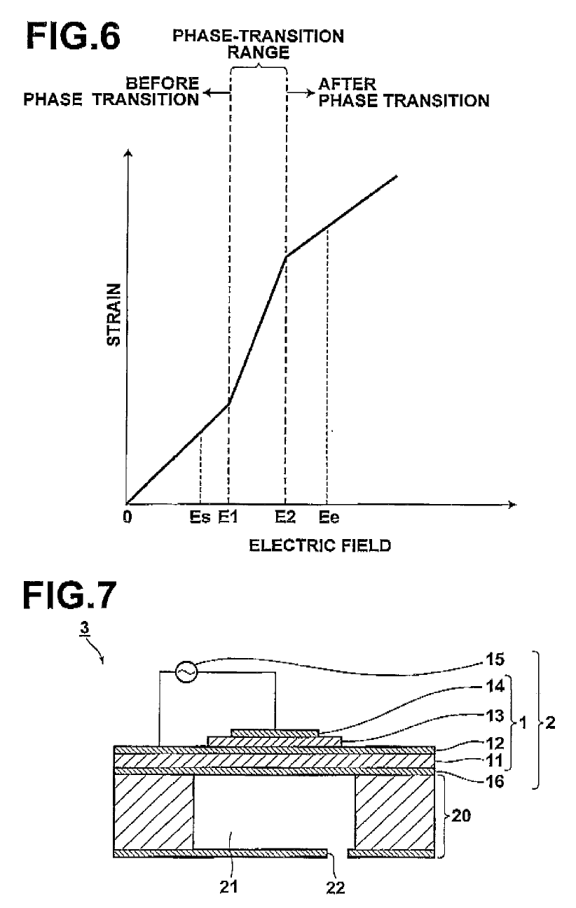

FIG. 6 is a quotation from “FIG. 2” of JP2007-116091A, and schematically shows a relationship between the strength of the electric field applied to the above ferroelectric body and the magnitude of strain produced in the ferroelectric body. In FIG. 6, Es is the minimum electric field strength, Ee is the maximum electric field strength, E1 is the minimum electric field strength at which the phase transition from the first ferroelectric phase begins, and E2 is the electric field strength at which the phase transition is substantially completed. The “electric field strength at which the phase transition is substantially completed” is such a level of the electric field strength that the phase transition no longer occurs even when the electric field strength becomes higher than the level. In some cases, even when the electric field strength becomes higher than E2, the phase transition does not occur in a portion of the first ferroelectric phase, so that the portion in the first ferroelectric phase remains unchanged. Although normally, E1<E2, E1 may be equal to E2 in some cases.

As indicated in FIG. 6, in the first range of the electric field strength E of 0 to E1 (before the beginning of the phase transition), the magnitude of strain of the ferroelectric body linearly increases with increase in the electric field strength because of the piezoelectric effect (producing the field-induced strain) in the first ferroelectric phase (before the phase transition). In the second range of the electric field strength E of E1 to E2, the magnitude of strain of the ferroelectric body also linearly increases with increase in the electric field strength because the change in the crystal structure associated with the phase transition causes a volume change in the ferroelectric body. In the third range of the electric field strength E greater than E2, the magnitude of strain of the ferroelectric body further linearly increases with increase in the electric field strength because of the piezoelectric effect (producing the field-induced strain) in the second ferroelectric phase (after the phase transition).

As explained above, the change in the crystal structure associated with phase transition causes the volume change in the ferroelectric body, and the piezoelectric effect (producing the field-induced strain) in the ferroelectric body works both before and after the phase transition since the ferroelectric body is formed with a ferroelectric phase both before and after the phase transition. Therefore, the ferroelectric body according to the present invention can achieve great strain in each of the first range of 0 to E1, the second range of E1 to E2, and the third range greater than E2.

Although no specific condition is imposed on the actuation of the ferroelectric body, when the magnitude of strain is considered, it is preferable to actuate the ferroelectric body so that the minimum electric field strength Es and the maximum electric field strength Ee satisfy the condition expressed by the inequalities (X).

Es<E1<Ee (X)

In addition, it is particularly preferable to actuate the ferroelectric body so that the minimum electric field strength Es and the maximum electric field strength Ee satisfy the condition expressed by the inequalities (Y).

Es<E1≦E2<Ee (Y)

Further, it is preferable that the first ferroelectric phase (which transitions to the second ferroelectric phase) have crystal orientation along a direction different from the orientation of the spontaneous-polarization axis, and it is more preferable that the second ferroelectric phase (after the phase transition) have crystal orientation along a direction approximately identical to the orientation of the spontaneous-polarization axis after the phase transition. Normally, the electric field is applied along the crystal orientation. It is particularly preferable to approximately equalize the direction of the applied electric field with the orientation of the spontaneous-polarization axis after the phase transition, since in this case the engineered-domain effect can work before the phase transition and make the magnitude of strain before the phase transition greater than the magnitude of strain achieved by equalizing the direction of the applied electric field with the orientation of the spontaneous-polarization axis before the phase transition. The engineered-domain effect in a monocrystal is explained in the aforementioned Park reference.

Furthermore, the phase transition can readily occur when the direction of the applied electric field is approximately identical to the orientation of the spontaneous-polarization axis after the phase transition. The present inventors consider that since the state in which the direction of the applied electric field is identical to the orientation of the spontaneous-polarization axis is crystallographically stable, transition to the more stable state can readily occur. In some cases, phase transition does not occur in a portion of the ferroelectric phase even when the electric field higher than the electric field strength E2 is applied to the ferroelectric body. However, when the phase transition efficiently proceeds, it is possible to reduce the portion the ferroelectric phase in which the phase transition does not occur even when the electric field higher than the electric field strength E2 is applied to the ferroelectric body. Therefore, in the case where the direction of the applied electric field is approximately identical to the orientation of the spontaneous-polarization axis after the phase transition, it is possible to stably achieve greater strain than in the case where the direction of the applied electric field is identical to the orientation of the spontaneous-polarization axis before the phase transition.

Moreover, in the case where the direction of the applied electric field is approximately identical to the orientation of the spontaneous-polarization axis after the phase transition, the piezoelectric effect (producing the field-induced strain) effectively works in the ferroelectric phase after the phase transition, so that it is possible to stably achieve great strain.

As explained above, in the case where the direction of the applied electric field is approximately identical to the orientation of the spontaneous-polarization axis after the phase transition, it is possible to achieve great strain before, during, and after the phase transition. This effect works at least when the direction of the applied electric field is different from the orientation of the spontaneous-polarization axis before the phase transition, and becomes more prominent as the direction of the applied electric field approaches the orientation of the spontaneous-polarization axis after the phase transition.

Therefore, it is preferable that the ferroelectric body according to the present invention contain one or more ferroelectric phases each having crystal orientation along a direction different from the spontaneous-polarization axis. In this case, it is further preferable that the one or more ferroelectric phases be at least one of a rhombohedral phase having crystal orientation along approximately the <100> direction, a rhombohedral phase having crystal orientation along approximately the <110> direction, a tetragonal phase having crystal orientation along approximately the <110> direction, a tetragonal phase having crystal orientation along approximately the <111> direction, an orthorhombic phase having crystal orientation along approximately the <100> direction, and an orthorhombic phase having crystal orientation along approximately the <111> direction. Further, it is also preferable that the one or more ferroelectric phases have such a property that phase transition occurs in at least part of the one or more ferroelectric phases when an electric field is applied to the ferroelectric body along a direction different from the directions of the spontaneous-polarization axes of the one or more ferroelectric phases.

As explained above, the oxide body formed of one or more of ferroelectric materials and antiferroelectric materials which exhibit asymmetric double hysteresis in the bipolar polarization-electric field characteristic has been first realized by the present invention. As mentioned before, when application of the electric field is stopped, the materials having the double-hysteresis polarization-electric field characteristic are restored to the initial state in which the residual polarization value Pr is zero or near to zero. Therefore, it is possible to expect to achieve greater displacement in the materials having the double-hysteresis polarization-electric field characteristic than in the materials having the single-hysteresis polarization-electric field characteristic, since relatively great residual polarization remains in the materials having the single-hysteresis polarization-electric field characteristic. In addition, since the double hysteresis in the bipolar polarization-electric field characteristic of the oxide body according to the present invention is asymmetric (i.e., imbalanced toward the positive-polarization side or the negative-polarization side), it is possible to expect to achieve further great displacement by actuating the oxide body in a unipolar mode on one of the positive-polarization side and the negative-polarization side on which greater displacement can be achieved.

The ferroelectric film which exhibits asymmetric double hysteresis in the bipolar polarization-electric field characteristic has been first realized by the present invention.

### 2. Piezoelectric Device and Inkjet Recording Head

Hereinbelow, the structures of a piezoelectric device as an embodiment of the present invention and an inkjet recording head (as a liquid discharge device) using the piezoelectric device are explained with reference to FIG. 7, which schematically shows a cross section (in the thickness direction) of an essential portion of the inkjet recording head containing the piezoelectric device. In FIG. 7, the respective elements are illustrated schematically, and the dimensions of the illustrated elements are different from the dimensions of the elements of the actual system.

As illustrated in FIG. 7, the inkjet recording head 3 contains a piezoelectric actuator 2 and an ink nozzle 20, and the piezoelectric actuator 2 includes a piezoelectric device 1.

The piezoelectric device 1 is a device produced by forming on a surface of a substrate 11, a lower electrode 12, a ferroelectric (piezoelectric) body 13, and an upper electrode 14 in this order in such a manner that an electric field can be applied to the ferroelectric body 13 through the lower electrode 12 and the upper electrode 14. The ferroelectric body 13 is an embodiment of the oxide body according to the first aspect of the present invention, which exhibits asymmetric double hysteresis in the bipolar polarization-electric field characteristic loop.

The material (composition) of the substrate 11 is not specifically limited. For example, the substrate 11 may be made of silicon, glass, stainless steel (for example, a stainless steel in accordance with JIS (Japanese Industrial Standard)), YSZ (yttrium stabilized zirconia), alumina, sapphire, SiC, SrTiO₃, or the like. In addition, the substrate 11 may be realized by a laminated substrate such as the SOI (silicon-on-insulator) substrate, which is produced by alternately forming on a surface of a silicon substrate one or more oxide films of SiO₂ and one or more Si active layers.

The main component of the lower electrode 12 is not specifically limited, and may be, for example, one or a combination of metals such as Au, Pt, and Tr, metal oxides such as IrO₂, RuO₂, LaNiO₃, and SrRuO₃.

The main component of the upper electrodes 14 is not specifically limited, and may be, for example, one or a combination of metals such as Au, Pt, and Ir, metal oxides such as IrO₂, RuO₂, LaNiO₃, and SrRuO₃, and the materials which are generally used for electrodes in the semiconductor processes, such as Al, Ta, Cr, and Cu.

Although the thicknesses of the lower electrode 12 and the upper electrodes 14 are not specifically limited, it is preferable that the thicknesses of the lower electrode 12 and the upper electrodes 14 be 50 to 500 nm.

The piezoelectric actuator 2 further includes a diaphragm 16 and a controller 15 as well as the piezoelectric device 1. The diaphragm 16 is attached to the back surface of the substrate 11 so that the diaphragm 16 can vibrate in response to expansion and contraction of the ferroelectric body 13. The controller 15 includes a driver circuit and the like for driving the piezoelectric device 1.

In outline, the inkjet recording head 3 is produced by attaching the ink nozzle 20 to the back surface of the piezoelectric actuator 2. The ink nozzle 20 is a member for reserving and discharging ink, and comprises an ink chamber 21 (as a liquid-reserve chamber) and an ink outlet 22 (as a liquid-discharge outlet) connected to the ink chamber 21. The ink chamber 21 reserves ink, and the ink held in the ink chamber 21 is discharged out of the ink chanter 21 through the ink outlet 22.

In the inkjet recording head 3, the strength of the electric field applied to the piezoelectric device 1 is increased or decreased so as to expand or contract the piezoelectric device 1 and control the discharge of the ink from the ink chamber 21 and the discharge amount of the ink.

Alternatively, it is possible to process portions of the substrate 11 into the diaphragm 16 and the ink nozzle 20, instead of separately preparing the diaphragm 16 and the ink nozzle 20 and attaching the diaphragm 16 and the ink nozzle 20 to the piezoelectric device 1. For example, in the case where the substrate 11 is formed by a laminated substrate such as the SOI substrate, the ink chambers 71 can be formed by etching the corresponding portions of the substrate 11 from the bottom surface of the substrate 11, and the diaphragm 16 and the structures of the ink nozzle 20 can be produced by processing the substrate 11 per se.

Since the piezoelectric device 1 comprises the ferroelectric body 13, which exhibits asymmetric double hysteresis in the bipolar polarization-electric field characteristic loop, the piezoelectric performance of the piezoelectric device 1 is superior.

### 3. Inkjet Recording Apparatus

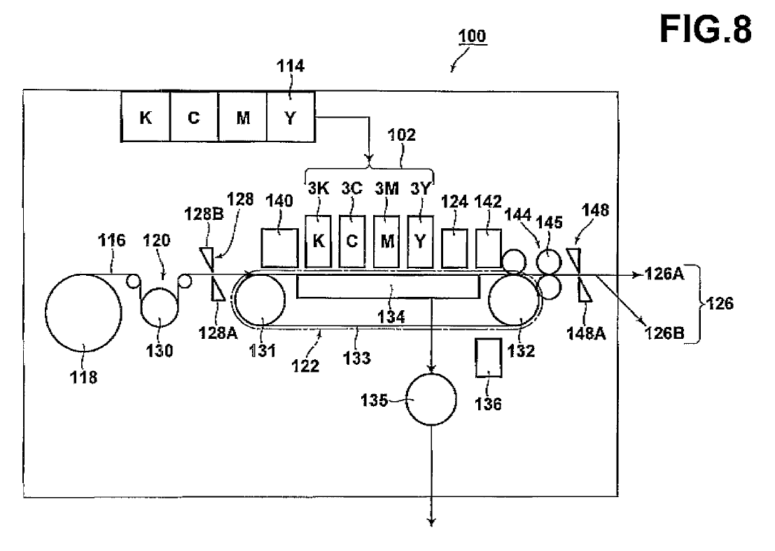

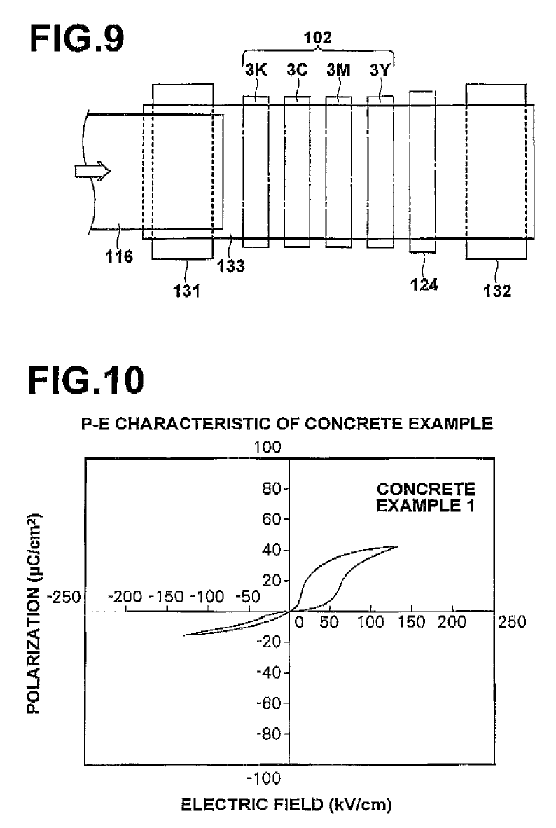

Hereinbelow, an example of an inkjet recording apparatus having the inkjet recording head 3 is explained with reference to FIGS. 8 and 9. FIG. 8 is a schematic diagram illustrating an outline of an example of an inkjet recording apparatus having the inkjet recording head 3 of FIG. 7, and FIG. 9 is a top view of a portion of the inkjet recording apparatus of FIG. 8.

As schematically illustrated in FIG. 8, the inkjet recording apparatus 100 comprises a printing unit 102, an ink reserve-and-load unit 114, a sheet feeding unit 118, a decurling unit 120, a suction-type belt conveyer 122, a print detection unit 124, and a sheet output unit 126. The printing unit 102 comprises a plurality of inkjet recording heads 3K, 3C, 3M, and 3Y corresponding to inks of different colors (specifically, black (K), cyan (C), magenta (M), and yellow (Y)). Hereinafter, the inkjet recording heads may be referred to as heads. The ink reserve-and-load unit 114 reserves the inks to be supplied to the heads 3K, 3C, 3M, and 3Y. The sheet feeding unit 118 feeds a recording sheet 116. The decurling unit 120 eliminates curl of the recording sheet 116. The suction-type belt conveyer 122 is arranged to face the nozzle faces (ink-discharge faces) of the printing unit 102, and conveys the recording sheet 116 while maintaining the flatness of the recording sheet 116. The print detection unit 124 reads an image printed on the recording sheet 116 by the printing unit 102. The sheet output unit 126 externally outputs a printed recording sheet 116.

Each of the heads 3K, 3C, 3M, and 3Y constituting the printing unit 102 corresponds to the inkjet recording head according to the present embodiment as explained before, although, in order to realize a linear head (explained later), each inkjet recording head used in the inkjet recording apparatus 100 comprises a plurality of piezoelectric devices on the lower electrode 12, and a plurality of ink chambers and a plurality of ink outlets are arranged in correspondence with the arrangement of the plurality of piezoelectric devices on the lower electrode 12.

The decurling unit 120 performs decurling of the recording sheet 116 by heating the recording sheet 116 with a heating drum 130 so as to eliminate the curl produced in the sheet feeding unit 118.

In the case where the inkjet recording apparatus 100 uses roll paper, a cutter 128 for cutting the roll paper into desired size is arranged in the stage following the decurling unit 120. The cutter 128 is constituted by a fixed blade 128A and a round blade 128B. The fixed blade 128A has a length equal to or greater than the width of the conveying path of the recording sheet 116, and is arranged on the side opposite to the print side of the recording sheet 116. The round blade 128B is arranged opposite to the fixed blade 128A on the print side of the recording sheet 116, and moves along the fixed blade 128A. In the inkjet recording apparatuses using cut paper, the cutter 128 in unnecessary.

After the roll paper is decurled and cut into the recording sheet 116, the recording sheet 116 is transferred to the suction-type belt conveyer 122. The suction-type belt conveyer 122 is constituted by rollers 131 and 132 and an endless belt 133. The rollers 131 and 132 are placed apart and the endless belt 133 is looped around the rollers 131 and 132 in such a manner that at least portions of the endless belt 133 which face the nozzle faces of the printing unit 102 and the sensor face of the print detection unit 124 are flat and horizontal.

The endless belt 133 has a width greater than the width of the recording sheet 116, and a great number of suction pores (not shown) are formed through the endless belt 133. A suction chamber 134 is arranged inside the loop of the endless belt 133 at the position opposite to the nozzle faces of the printing unit 102 and the sensor face of the print detection unit 124, and suctioned by a fan 135, so that a negative pressure is generated in the suction chamber 134, and the recording sheet 116 on the endless belt 133 is held by suction.

The power of a motor (not shown) is transmitted to at least one of the rollers 131 and 132 so that the endless belt 133 is driven clockwise in FIG. 8, and the recording sheet 116 held on the endless belt 133 is moved from left to right in FIG. 8.

In the case of borderless printing, ink can be deposited on the endless belt 133. Therefore, in order to clean the endless belt 133, a belt cleaning unit 136 is arranged at a predetermined (appropriate) position outside the loop of the endless belt 133 and the printing region.

A heating fan 140 is arranged on the upstream side of the printing unit 102 above the conveying path of the recording sheet 116 (which is realized by the suction-type belt conveyer 122). The heating fan 140 blows heated air to the recording sheet 116 before printing so as to heat the recording sheet 116 and facilitate drying of deposited ink.

Each of the heads 3K, 3C, 3M, and 3Y in the printing unit 102 is a so-called full-line type head, which is a linear head having a length corresponding to the maximum width of the recording sheet 116, and being arranged across the width of the recording sheet 116 (i.e., in the main scanning direction perpendicular to the feeding direction of the recording sheet 116) as illustrated in FIG. 9. Specifically, each of the heads 3K, 3C, 3M, and 3Y is a linear head in which the aforementioned plurality of ink-discharge outlets (nozzles) are arrayed over a length exceeding the maximum length of a side of the largest recording sheet 116 on which the inkjet recording apparatus 100 can print an image. The heads 3K, 3C, 3M, and 3Y corresponding to the inks of the different colors are arrayed upstream in this order along the feeding direction as illustrated in FIG. 9. Thus, a color image can be printed on the recording sheet 116 by discharging the inks of the different colors while conveying the recording sheet 116.

The print detection unit 124 may he constituted by, for example, a line sensor which takes an image formed of spots of the inks discharged from the printing unit 102, and detects, from the image taken by the line sensor, incomplete discharge, which can be caused by clogging of a nozzle or the like.

A rear drying unit 142 for drying the printed surface of the recording sheet 116 is arranged in the stage following the print detection unit 124. For example, the rear drying unit 142 is realized by a heating fan or the like. Since it is preferable to avoid contact with the printed surface before the ink on the printed surface is completely dried, it is preferable that the rear drying unit 142 dry the ink on the printed surface by blowing heated air.

In order to control the glossiness of the image printed on the recording sheet 116, a heating-and-pressurizing unit 144 is arranged in the stage following the rear drying unit 142. The heating-and-pressing unit 144 comprises a pressure roller 145 with a surface having predetermined projections and depressions, and transfers the predetermined projections and depressions to the printed surface of the recording sheet 116 by pressing the printed surface with the pressure roller 145 while heating the printed surface.

Finally, the printed recording sheet 116 produced as above is outputted from the sheet output unit 126. It is preferable to separately output test prints and prints for practical use. Therefore, the sheet output unit 126 includes a first output unit 126A for the prints for practical use and a second output unit 126B for the test prints. Although not shown, the inkjet recording apparatus 100 further comprises a sorting unit which sorts the printed recording sheets 116 into the test prints and the prints for practical use, and sends the test prints to the first output unit 126B, and the prints for practical use to the second output unit 126A.

Further, in the case where both of a test image and an image for practical use are concurrently printed on a recording sheet 116, it is possible to arrange a cutter 148, and separate a first portion of the recording sheet 116 on which the test image is printed and a second portion of the recording sheet 116 on which the image for practical use is printed.

### 4. Concrete Example of the Present Invention

The present inventors have produced a concrete example of the piezoelectric device according to the present invention and a comparison example of a conventional piezoelectric device as indicated below.

### 4.1 Production of Concrete Example

The concrete example of the piezoelectric device according to the present invention has been produced in accordance with the following procedure.

First, a lower electrode having a laminated structure of a Ti layer with a thickness of 20 nm and an Ir layer with a thickness of 260 nm has been formed on a (100) Si layer of an SOI (silicon-on-insulator) substrate by sputtering at the substrate temperature of 350° C. Then, a ferroelectric film of Nb-PZT having a thickness of 4.0 micrometers has been formed by sputtering at the substrate temperature of 525° C. At this time, a target of Pb(Ti, Zr, Nb)O₃ (in which the molar ratio between Zr and Ti is 47/53 and the Nb content at the B-sites is 12 mol %) is used, the input power is 200 W, the substrate-target distance is 60 nm, and the cooling time for cooling the ferroelectric film from the film-formation temperature to the ordinary temperature is five hours. Subsequently, an upper electrode of Au/Cu having a thickness of 150 nm has been formed. Thus, the piezoelectric device as the concrete example of the present invention has been obtained.

Thereafter, the back surface of the substrate is patterned by dry etching, and the substrate is processed so as to produce an ink nozzle having a diaphragm, an ink chamber, and an ink-discharge outlet. Thus, production of an inkjet recording head containing the concrete example of the piezoelectric device according to the present invention is completed.

### 4.2 Measurement of Concrete Example

### 4.2.1 Composition Analysis

The present inventors have performed composition analysis of the ferroelectric film in the concrete example by X-ray fluorescence (XRF) measurement, so that the molar ratios in the composition of the ferroelectric film in the concrete example have been obtained as follows.

Pb/(Ti+Zr+Nb)=1.1

Zr/Ti=47/53

Nb/(Ti+Zr+Nb)=0.12

### 4.2.2 Structural Analysis

The present inventors have performed X-ray diffraction (XRD) measurement of the ferroelectric film in the concrete example, and the result of the XRD measurement shows that the ferroelectric film in the concrete example is a (100) preferentially oriented, single-phase perovskite film with the degree of orientation of 95% or higher, and the crystal phase is a mixture of the tetragonal phase and the rhombohedral phase.

### 4.2.3 Electrical Characteristic

The present inventors have measured the bipolar polarization-electric field characteristic (P-E hysteresis characteristic) of the piezoelectric device as the concrete example of the present invention. In the measurement, the measurement frequency is set to 10 Hz, and the maximum applied voltage is set to 80 V (realizing the electric field of 200 kV/cm). FIG. 10 schematically shows a P-E hysteresis curve of the ferroelectric film in the concrete example. The P-E hysteresis curve of FIG. 10 passes through the vicinity of the origin of the coordinate plane of the polarization and the electric field, and exhibits asymmetric double hysteresis imbalanced toward the positive-polarization side. The residual polarization value Pr of 2.7 μC/cm² and the dielectric constant ε of 1,085 have been obtained from the measurement.

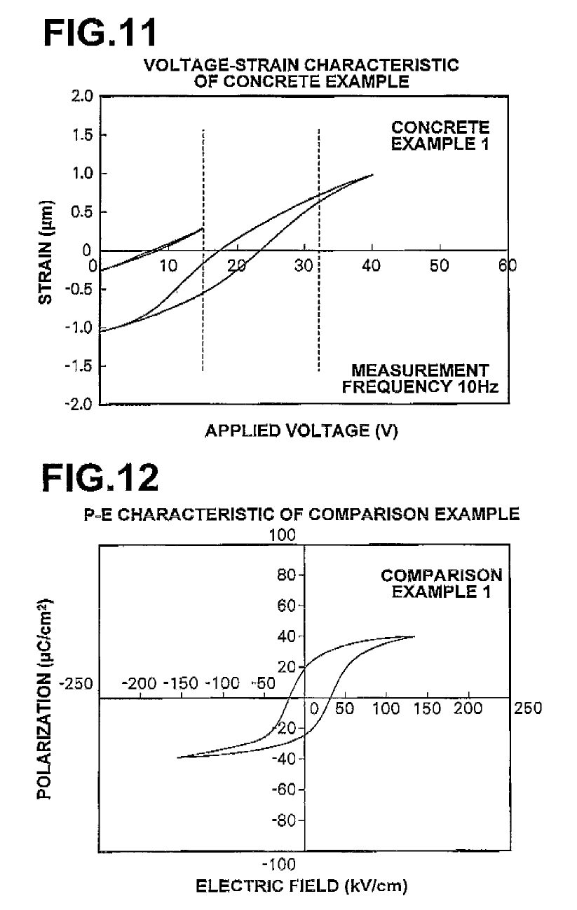

The present inventors have measured the voltage-strain characteristic of the ferroelectric film in the concrete example at the measurement frequency of 10 Hz. FIG. 11 schematically shows a unipolar voltage-strain characteristic curve of the ferroelectric film in the concrete example. The piezoelectric constant d₃₁ of 210 pm/V have been obtained from the measurement.

Further, the present inventors have also confirmed that ferroelectric films having characteristics similar to the above can be obtained by using PLD instead of sputtering.

### 4.3 Production of Comparison Example

The comparison example of a piezoelectric device has been produced in a similar manner to the concrete example except that the cooling time for cooling the ferroelectric film from the film-formation temperature to the ordinary temperature in the cooling process after the formation of the ferroelectric film is 0.5 hours.

### 4.4 Measurement of Comparison Example

### 4.4.1 Composition Analysis

The present inventors have performed composition analysis of the ferroelectric film in the comparison example by X-ray fluorescence (XRF) measurement in a similar manner to the concrete example, so that the molar ratios in the composition of the ferroelectric film in the comparison example have been obtained as follows.

Pb/(Ti+Zr+Nb)=1.17

Zr/Ti=48/52

Nb/(Ti+Zr+Nb)=0.10

### 4.4.2 Structural Analysis

The present inventors have performed X-ray diffraction (XRD) measurement of the ferroelectric film in the comparison example in a similar manner to the concrete example, and the result of the XRD measurement shows that the ferroelectric film in the comparison example is a (100) preferentially oriented, single-phase perovskite film with the degree of orientation of 95% or higher, and the crystal phase is a mixture of the tetragonal phase and the rhombohedral phase.

### 4.4.3 Electrical Characteristic

The present inventors have measured the bipolar polarization-electric field characteristic (P-E hysteresis characteristic) of the piezoelectric device as the comparison example in a similar manner to the concrete example. FIG. 12 schematically shows the P-E hysteresis curve of the ferroelectric film in the comparison example. The P-E hysteresis curve of FIG. 12 exhibits normal single hysteresis. The residual polarization value Pr of 21.5 μC/cm² and the dielectric constant ε of 1,267 have been obtained from the measurement.

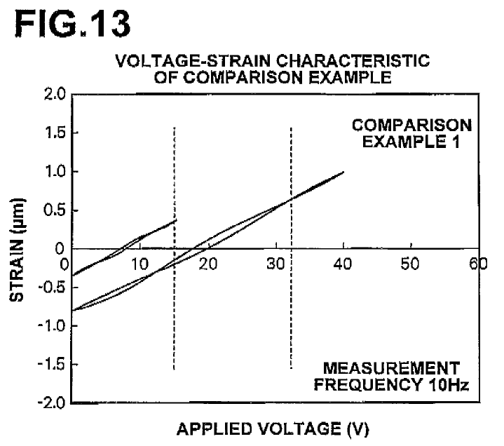

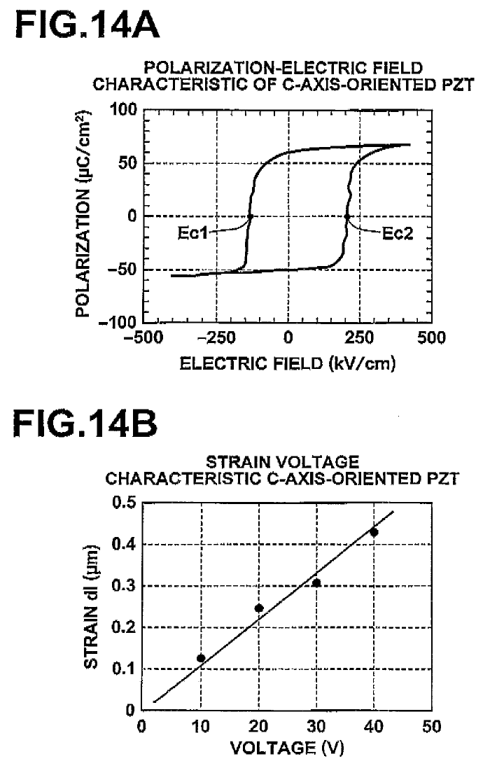

The present inventors have measured the voltage-strain characteristic of the ferroelectric film in the comparison example at the measurement frequency of 10 Hz. FIG. 13 schematically shows a unipolar voltage-strain characteristic curve of the ferroelectric film in the comparison example. The piezoelectric constant d₃₁ of 200 pm/V have been obtained from the measurement.

The results of the measurement of the concrete example and the comparison example are summarized in Table 1.

TABLE 1

| | Concrete Example | Comparison Example |
|---|---|---|
| Type | Ferroelectric | Ferroelectric |
| Form | Film | Film |
| Composition | Nb-PZT | Nb-PZT |
| Pb/(Zr + Ti + Nb) | 1.1 | 1.17 |
| Zr/Ti | 47/53 | 48/52 |
| Nb/(Zr + Ti + Nb) (%) | 12 | 10 |
| Orientation | 100 | 100 |
| Crystal Phase | MPB | MPB |
| Cooling Time After | 5 hr | 0.5 hr |
| Film Formation | | |
| P-E Hysteresis | Asymmetric Double | Single Hysteresis |
| | Hysteresis | |
| ε | 1085 | 1267 |
| Pr (μC/cm²) | 2.7 | 21.5 |
| d₃₁ (pm/V) | 210 | 200 |

### 5. Industrial Usability

The oxide body according to the present invention can be preferably used in piezoelectric actuators, ferroelectric memories (FRAMs), and the like, where the piezoelectric actuators may be mounted in the inkjet recording heads, the magnetic recording-and-reproduction heads, MEMS (micro electromechanical systems) devices, micropumps, ultrasonic probes, and the like.

What is claimed is:

1. An oxide body formed of one or more of ferroelectric materials and antiferroelectric materials which exhibit asymmetric double hysteresis in a bipolar polarization-electric field characteristic obtained under a condition that a maximum value of an electric field applied to the oxide body and a magnitude of a minimum value of the electric field are equal, where a curve indicating the bipolar polarization-electric field characteristic has at least five points of inflection, and a maximum value of polarization of the oxide body and a magnitude of a minimum value of the polarization are different.

2. An oxide body according to claim 1, wherein said maximum value of the polarization of the oxide body is greater than the magnitude of the minimum value of the polarization.

3. An oxide body according to claim 1, wherein said maximum value of the polarization of the oxide body is smaller than said magnitude of the minimum value of the polarization.

4. An oxide body according to claim 1, formed of one or more ferroelectric materials.

5. An oxide body according to claim 4, wherein said one or more ferroelectric materials are one or more perovskite oxides.

6. An oxide body according to claim 5, wherein said one or more ferroelectric materials are a perovskite oxide or a mixture of perovskite oxides, and each of said perovskite oxide and said perovskite oxides is expressed by a compositional formula ABO₃, A represents one or more A-site elements which are one or more of Pb, Ba, La, Sr, Bi, Li, Na, Ca, Cd, Mg, K, and the lanthanide elements, B represents one or more B-site elements which are one or more of Ti, Zr, V, Nb, Ta, Cr, Mo, W, Mn, Mg, Sc, Co, Cu, In, Sn, Ga, Zn, Cd, Fe, Ni, Hf, and Al, O represents oxygen, and the ratio of each of the total molar amount of atoms of the one or more A-site elements and the total molar amount of atoms of the one or more B-site elements to the molar amount of oxygen atoms in each perovskite oxide may deviate from 1:3 within a range in which a perovskite structure can be formed.

7. An oxide body according to claim 6, wherein in at least one of said perovskite oxide and said perovskite oxides, one or more A-site elements are one or more metal elements of Pb, Bi, Ba, Sr, Ca, La, and Mg, and one or more B-site elements are a combination of one or more metal elements of Zr, Ti, Fe, and Al and one or more metal elements of Co, Mn, Mg, Ni, Zn, V, Nb, Ta, Cr, Mo, and W.

8. An oxide body according to claim 4, containing one or more ferroelectric phases each having crystal orientation.

9. An oxide body according to claim 8, wherein said one or more ferroelectric phases include one or both of a (100)-oriented ferroelectric phase and a (111)-oriented ferroelectric phase.

10. An oxide body according to claim 9, wherein said one or more ferroelectric phases include a (100)-oriented tetragonal phase.

11. An oxide body according to claim 9, wherein said one or more ferroelectric phases include a (111)-oriented rhombohedral phase.

12. An oxide body according to claim 4, having a composition equal or near to an MPB (morphotropic phase boundary) composition.

13. An oxide body according to claim 8, wherein at least one of the one or more ferroelectric phases has crystal orientation along a first direction and a spontaneous-polarization axis along a second direction different from the first direction.

14. An oxide body according to claim 13, wherein said one or more ferroelectric phases are at least one of a rhombohedral phase having crystal orientation along approximately <100> direction, a rhombohedral phase having crystal orientation along approximately a <110> direction, a tetragonal phase having crystal orientation along approximately a <110> direction, a tetragonal phase having crystal orientation along approximately a <111> direction, an orthorhombic phase having crystal orientation along approximately a <100> direction, and an orthorhombic phase having crystal orientation along approximately a <111> direction.

15. An oxide body according to claim 13, wherein at least part of each of at least one of said one or more ferroelectric phases transitions to at least one other ferroelectric phase each corresponding to a crystal system different from a crystal system corresponding to said each of at least one of said one or more ferroelectric phases, when an electric field is applied to said oxide body along a direction different from said second direction.

16. An oxide body according to claim 1, being an oxide film formed on a substrate.

17. A piezoelectric device comprising:
a piezoelectric body realized by said oxide body according to claim 4; and
electrodes through which said electric field can be applied to the piezoelectric body along a thickness direction of the piezoelectric body.

18. A liquid discharge device comprising:
said piezoelectric device according to claim 17; and
a discharge member including,
a liquid-reserve chamber which reserves liquid, and
a liquid-discharge outlet through which said liquid is discharged from the liquid-reserve chamber.
